(19) United States
(12) Patent Application Publication
(10) Pub. No.: US 2025/0081822 A1
(43) Pub. Date: Mar. 6, 2025

(54) DISPLAY PANEL AND METHOD FOR MANUFACTURING SAME, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Ping WEN, Beijing (CN); Chang LUO, Beijing (CN); Yi ZHANG, Beijing (CN); Zeyu LI, Beijing (CN); Conglei ZHANG, Beijing (CN); Bo SHI, Beijing (CN)

(21) Appl. No.: 18/283,240

(22) PCT Filed: Nov. 15, 2022
(86) PCT No.: PCT/CN2022/131997

§ 371 Date: Sep. 21, 2023

(30) Foreign Application Priority Data
Jun. 29, 2022 (CN) 202210763493.9

(51) Int. Cl. H10K 59/80; H10K 59/12; H10K 59/131

(52) U.S. Cl. CPC H10K 59/879; H10K 59/1201; H10K 59/131

(57) ABSTRACT

Provided is a display panel, including a driver backplane, a light-emitting functional layer, and a light-extraction layer. The light-emitting functional layer and the light-extraction layer are successively stacked on a bearing surface of the driver backplane. The light-emitting functional layer includes a plurality of light-emitting units arranged in arrays. The light-extraction layer includes a first sub-layer and a second sub-layer, which are successively stacked on the light-emitting functional layer. A refractive index of the first sub-layer is less than a refractive index of the second sub-layer. A plurality of grooves are defined in the first sub-layer, and each of the plurality of grooves is opposite to one of the plurality of light-emitting units. A portion of the second sub-layer is within the plurality of grooves. A boundary length of the groove is greater than a boundary length of a light-emitting region of the corresponding one of the light-emitting units.

The present disclosure is a U.S. national stage of international application No. PCT/CN2022/131997, field on Nov. 15, 2022, which claims priority to Chinese Patent Application No. 202210763493.9, filed on Jun. 29, 2022 and entitled “DISPLAY PANEL AND METHOD FOR MANUFACTURING SAME, AND DISPLAY DEVICE,” the contents of which are herein incorporated by reference in their entireties.

### TECHNICAL FIELD

The present disclosure relates to the field of display technologies, and in particular, relates to a display panel and a method for manufacturing the same, and a display device.

### BACKGROUND

Organic light-emitting diode (OLED) display panels have a multilayer-film structure. After exiting from a light-emitting functional layer, light is reflected and refracted by a multi-film layer disposed on the light-emitting functional layer, which leads to a great loss of light. Consequently, a light-exiting effect of the display panel is adversely affected.

### SUMMARY

Some embodiments of the present disclosure provide a display panel and a method for manufacturing the same, and a display device. The technical solutions are as follows.

According to some embodiments of the present disclosure, a display panel is provided. The display panel includes a driver backplane, a light-emitting functional layer, and a light-extraction layer, the light-emitting functional layer and the light-extraction layer being successively disposed on a bearing surface of the driver backplane; wherein the light-emitting functional layer includes a plurality of light-emitting units arranged in arrays; and the light-extraction layer includes a first sub-layer and a second sub-layer, wherein the first sub-layer and the second sub-layer are successively stacked on the light-emitting functional layer, a refractive index of the first sub-layer is less than a refractive index of the second sub-layer, a plurality of grooves are defined in the first sub-layer, each of the plurality of grooves is opposite to one of the plurality of light-emitting units, a portion of the second sub-layer is within the plurality of grooves, and a boundary length of the groove is greater than a boundary length of a light-emitting region of the corresponding one of the light-emitting units.

In some embodiments, at least a portion of an outer profile of an orthographic projection of the groove on the bearing surface is within an orthographic projection of the corresponding light-emitting unit on the bearing surface.

In some embodiments, a protrusion is formed on a side wall of at least one of the plurality of grooves, wherein the protrusion protrudes along a direction toward a center of the groove, and at least a portion of an outer profile of an orthographic projection of the protrusion on the bearing surface is within the orthographic projection of the light-emitting unit on the bearing surface.

In some embodiments, an orthographic projection of the light-emitting unit on the bearing surface is within an outer profile of an orthographic projection of the groove on the bearing surface.

In some embodiments, a protrusion is formed on a side wall of at least one of the plurality of grooves, the protrusion protruding along a direction toward a center of the groove.

In some embodiments, a maximum length of the protrusion ranges from 1 μm to 3 μm, and a maximum width of the protrusion ranges from 1 μm to 5 μm.

In some embodiments, a shape of a section, parallel to the bearing surface, of the protrusion includes an arc.

In some embodiments, an outer wall surface of the protrusion is a conical surface, and a large-sized end of the protrusion is proximal to the light-emitting unit.

In some embodiments, an outer wall surface of the protrusion is a cylindrical surface, a straight generatrix of the cylindrical surface being parallel to the side wall of the groove.

In some embodiments, a plurality of the protrusions are provided, and the plurality of the protrusions are spaced apart around a geometric center of the groove.

In some embodiments, the groove has a plurality of side walls successively connected end to end, at most one of the protrusions is formed on each of the side walls of the groove.

In some embodiments, the plurality of light-emitting units include a first light-emitting unit, the groove corresponding to the first light-emitting unit includes a first side wall, a third side wall, a second side wall, and a fourth side wall that are successively connected, and one of the protrusions is formed on each of the side walls of the groove; wherein a line connecting a geometrical center of the protrusion of the first side wall to a geometrical center of the protrusion of the second side wall is a first connection line, the first connection line being intersected with an extension line of a side edge, proximal to the first light-emitting unit, of the third side wall or an extension line of a side edge, proximal to the first light-emitting unit, of the fourth side wall; or a line connecting a geometrical center of the protrusion of the third side wall to a geometrical center of the protrusion of the fourth side wall is a second connection line, the second connection line being intersected with an extension line of a side edge, proximal to the first light-emitting unit, of the first side wall or an extension line of a side edge, proximal to the first light-emitting unit, of the second side wall.

In some embodiments, each of the first side wall, the second side wall, the third side wall, and the fourth side wall include a straight line segment; wherein at least one side edge of the first side wall, the second side wall, the third side wall, and the fourth side wall further includes a curved line segment, the curved line segment being connected to an end of the straight line segment of the side edge on which the curved line segment is disposed; and the protrusions on the first side wall, the second side wall, the third side wall, and the fourth side wall are respectively disposed at midpoints of the corresponding straight line segments.

In some embodiments, the plurality of light-emitting units are arranged in a matrix in a first direction and a second direction, wherein the first connection line is intersected with both the first direction and the second direction, and/or the second connection line is intersected with both the first direction and the second direction.

In some embodiments, the plurality of light-emitting units further include a second light-emitting unit and a third light-emitting unit, each of the second light-emitting unit and the third light-emitting unit including four successively connected side walls and protrusions respectively disposed on the side walls; wherein the opposite two protrusions on the second light-emitting unit are arranged along a first straight line or a second straight line, and the opposite two protrusions on the third light-emitting unit are arranged along the first straight line or the second straight line, the first straight line being parallel to the first direction and the second straight line being parallel to the second direction.

In some embodiments, each of the first side wall and the fourth side wall of the first light-emitting unit includes a straight line segment and a curved line segment, wherein the curved line segment of the first side wall is connected to the curved line segment of the fourth side wall, and the connected two curved line segments form a fillet; and the protrusion on the first side wall of the first light-emitting unit is not overlapped with the second straight line, the protrusion on the fourth side wall of the first light-emitting unit is not overlapped with the first straight line, the protrusion on the second side wall of the first light-emitting unit is on the second straight line, and the protrusion on the third side wall of the first light-emitting unit is on the first straight line; or the protrusion on the first side wall of the first light-emitting unit is on the second straight line, the protrusion on the fourth side wall of the first light-emitting unit is on the first straight line, the protrusion on the second side wall of the first light-emitting unit is not overlapped with the second straight line, and the protrusion on the third side wall of the first light-emitting unit is not overlapped with the first straight line.

In some embodiments, the protrusion is in the shape of a box, and a geometric center of the protrusion is consistent with a geometric center of the groove.

In some embodiments, a recessed portion is defined in a side wall of the groove; wherein the recessed portion is recessed along a direction away from a geometrical center of the groove, and the recessed portion is disposed at least in a side surface, proximal to the light-emitting functional layer, of the first sub-layer; and at least a portion of an orthographic projection of the recessed portion on the bearing surface is outside an orthographic projection of the corresponding light-emitting unit on the bearing surface.

In some embodiments, a shape of the orthographic projection of the recessed portion on the bearing surface includes at least one of a rectangle, a trapezoid, a triangle, or an arc.

In some embodiments, a recessed depth of the recessed portion is not greater than 5 μm.

In some embodiments, the groove has a first opening and a second opening, wherein the first opening is disposed in a side surface, proximal to the driver backplane, of the first sub-layer, and the second opening is disposed in a side surface, distal from the driver backplane, of the first sub-layer, and an orthographic projection of the first opening on the bearing surface is within an orthographic projection of the second opening on the bearing surface.

In some embodiments, an included angle between a side wall of the groove and the driver backplane ranges from 400 to 80°.

In some embodiments, a side wall of the groove includes a plurality of planar surfaces successively connected between the first opening and the second opening, an included angle being defined between connected two planar surfaces.

In some embodiments, a side wall of the groove is a curved surface, and the side wall of the groove is recessed along a direction away from a center of the groove.

In some embodiments, the grooves are in one-to-one correspondence to the light-emitting units.

In some embodiments, the first sub-layer is a transparent optical material layer or an ink material layer, and the second sub-layer is a transparent optical material layer or an ink material layer.

In some embodiments, the display panel further includes a touch control layer and a package layer, wherein the package layer and the touch control layer are successively stacked between the light-emitting functional layer and the light-extraction layer, and the first sub-layer and the second sub-layer are successively stacked on the touch control layer.

According to some embodiments of the present disclosure, a method for manufacturing a display panel is provided. The method includes: providing a driver backplane; forming a light-emitting functional layer on a bearing surface of the driver backplane, wherein the light-emitting functional layer includes a plurality of light-emitting units arranged in arrays; and forming a light-extraction layer on the light-emitting functional layer, the light-extraction layer including a first sub-layer and a second sub-layer, wherein the first sub-layer and the second sub-layer are successively stacked on the light-emitting functional layer, a refractive index of the first sub-layer is less than a refractive index of the second sub-layer, a plurality of grooves are defined in the first sub-layer, each of the plurality of grooves is opposite to one of the plurality of light-emitting units, a portion of the second sub-layer is within the plurality of grooves, and a boundary length of the groove is greater than a boundary length of a light-emitting region of the corresponding one of the light-emitting units.

According to some embodiments of the present disclosure, a display device is provided. The display device includes: a power supply component and the display panel as described above, wherein the power supply component is electrically connected to the display panel.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a planar schematic diagram of a display panel according to some embodiments of the present disclosure;

FIG. 2 is a sectional schematic diagram of a display panel according to some embodiments of the present disclosure;

FIG. 3 is a diagram of a projection relation between a first sub-layer and a light-emitting unit according to some embodiments of the present disclosure;

FIG. 4 is a sectional schematic diagram of a display panel according to some embodiments of the present disclosure;

FIG. 5 is a schematic structural diagram of a light-extraction layer according to some embodiments of the present disclosure;

FIG. 6 is a schematic structural diagram of a light-extraction layer according to some embodiments of the present disclosure;

FIG. 7 is a schematic structural diagram of a light-extraction layer according to some embodiments of the present disclosure;

FIG. 8 is a partially schematic structural diagram of a first sub-layer according to some embodiments of the present disclosure;

FIG. 9 is a partially schematic structural diagram of another first sub-layer according to some embodiments of the present disclosure;

FIG. 10 is a partially schematic structural diagram of still another first sub-layer according to some embodiments of the present disclosure;

FIG. 11 is a planar schematic diagram of a first sub-layer according to some embodiments of the present disclosure;

FIG. 12 is a planar schematic diagram of a first sub-layer according to some embodiments of the present disclosure;

FIG. 13 is a distribution schematic diagram of light-emitting units according to some embodiments of the present disclosure;

FIG. 14 is a schematic structural diagram of a light-emitting unit according to some embodiments of the present disclosure;

FIG. 15 is a distribution schematic diagram of light-emitting units according to some embodiments of the present disclosure;

FIG. 16 is a sectional schematic diagram of a display panel according to some embodiments of the present disclosure;

FIG. 17 is a schematic structural diagram of a light-emitting unit according to some embodiments of the present disclosure;

FIG. 18 is a sectional schematic diagram of a display panel according to some embodiments of the present disclosure;

FIG. 19 is a schematic structural diagram of a light-emitting unit according to some embodiments of the present disclosure;

FIG. 20 is a sectional schematic diagram of a display panel according to some embodiments of the present disclosure;

FIG. 21 is a partially schematic structural diagram of a first sub-layer according to some embodiments of the present disclosure;

FIG. 22 is a top view of a first sub-layer according to some embodiments of the present disclosure;

FIG. 23 is a planar schematic diagram of a first sub-layer according to some embodiments of the present disclosure;

FIG. 24 is a sectional view of a first sub-layer according to some embodiments of the present disclosure;

FIG. 25 is a planar schematic diagram of a first sub-layer according to some embodiments of the present disclosure;

FIG. 26 is a planar schematic diagram of a first sub-layer according to some embodiments of the present disclosure;

FIG. 27 is a planar schematic diagram of a first sub-layer according to some embodiments of the present disclosure;

FIG. 28 is a planar schematic diagram of a first sub-layer according to some embodiments of the present disclosure;

FIG. 29 is a planar schematic diagram of a first sub-layer according to some embodiments of the present disclosure;

FIG. 30 is a planar schematic diagram of a first sub-layer according to some embodiments of the present disclosure;

FIG. 31 is a planar schematic diagram of a first sub-layer according to some embodiments of the present disclosure;

FIG. 32 is a sectional schematic diagram of a display panel according to some embodiments of the present disclosure; and

FIG. 33 is a flowchart of a method for manufacturing a display panel according to some embodiments of the present disclosure.

### REFERENCE NUMERALS AND DENOTATIONS THEREOF

10—driver backplane;
20—light-emitting functional layer; 21—light-emitting unit; 22—package layer; 23—pixel-definition layer;
30—light-extraction layer; 31—first sub-layer; 310—groove; 311—first opening; 312—second opening; 32—second sub-layer; 301—first side wall; 302—second side wall; 303—third side wall; 304—fourth side wall; 305—straight line segment; 306—curved line segment;
40—protrusion;
50—recessed portion;
60—touch control layer; and
O—straight generatrix; A1—first connection line; A2—second connection line; X—first direction; Y—second direction; B1—first straight line; B2—second straight line; F1—first light-emitting unit; F2—second light-emitting unit; and F3—third light-emitting unit.

### DETAILED DESCRIPTION

The present disclosure is described in further detail with reference to the accompanying drawings, to clearly present the objects, technical solutions, and advantages of the present disclosure.

It should be noted that unless otherwise defined, technical or scientific terms used in the embodiments of the present disclosure shall have ordinary meanings understandable by persons of ordinary skill in the art to which the disclosure belongs. The terms “first,” “second,” and the like used in the embodiments of the present disclosure are not intended to indicate any order, quantity or importance, but are merely used to distinguish the different components. The terms “comprise,” “include,” and derivatives or variations thereof are used to indicate that the element or object preceding the terms covers the element or object following the terms and its equivalents, and shall not be understood as excluding other elements or objects. The terms “connect,” “contact,” and the like are not intended to be limited to physical or mechanical connections, but may include electrical connections, either direct or indirect connection. The terms “on,” “under,” “left,” and “right” are only used to indicate the relative positional relationship. When the absolute position of the described object changes, the relative positional relationship may change accordingly.

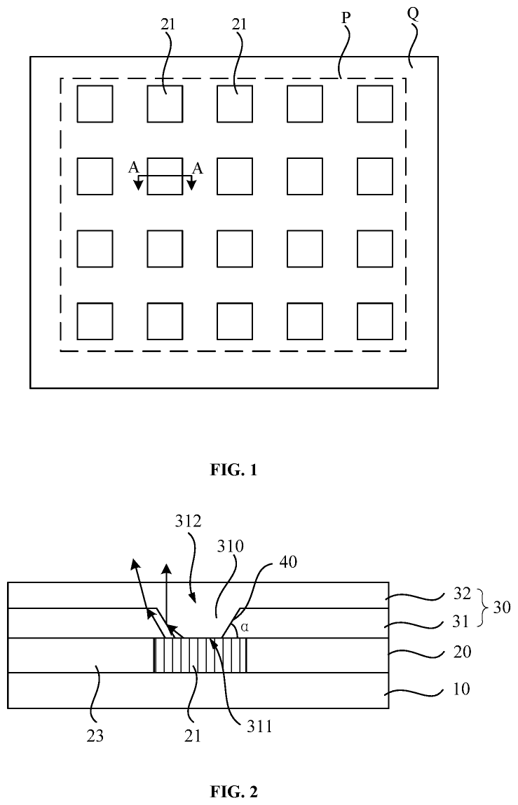

FIG. 1 is a planar schematic diagram of a display panel according to some embodiments of the present disclosure. As illustrated in FIG. 1, the display panel includes a display region P, a non-display region Q surrounding the display region P, and a plurality of light-emitting units 21 arranged in arrays in the display region P. The description of the structure of the display panel is given using a section of one of the light-emitting units as an example.

FIG. 2 is a sectional schematic diagram of a display panel according to some embodiments of the present disclosure. As illustrated in FIG. 2, the display panel includes a driver backplane 10, a light-emitting functional layer 20, and a light-extraction layer 30. The light-emitting functional layer 20 and the light-extraction layer 30 are successively disposed on a bearing surface of the driver backplane 10.

The bearing surface refers to a surface of the driver backplane 10 to bear other film layers. In some embodiments, in the case that the light-emitting functional layer is formed on the driver backplane, a surface, in contact with the light-emitting functional layer 20, of the driver backplane 10 is the bearing surface.

As illustrated in FIG. 2, the light-emitting functional layer 20 includes a plurality of light-emitting units 21 arranged in arrays. The light-emitting functional layer includes a pixel-definition layer 23, and the pixel-definition layer 23 has a plurality of openings. Each of the openings is arranged with one light-emitting unit 21 therein. An extent of the opening in the pixel-definition layer 23 is an extent of an outer profile of the light-emitting unit 21.

As illustrated in FIG. 2, the light-extraction layer 30 includes a first sub-layer 31 and a second sub-layer 32 that are successively stacked on the light-emitting functional layer 20. A refractive index of the first sub-layer 31 is less than that of the second sub-layer 32. A plurality of grooves 310 (only one of the grooves is illustrated in FIG. 2) are defined in the first sub-layer 31. The grooves 310 are in one-to-one correspondence to the light-emitting units 21, and a portion of the second sub-layer 32 is within the plurality of grooves 310.

A boundary length of the groove 310 is greater than a boundary length of a light-emitting region of a corresponding light-emitting unit 21. The boundary length of the groove is a circumference of an outer profile of the groove. The boundary length of the light-emitting region of the light-emitting unit is a circumference of an outer profile of the light-emitting region of the light-emitting unit.

In the display panel according to some embodiments of the present disclosure, the driver backplane 10, the light-emitting functional layer 20, and the light-extraction layer 30 are successively stacked, wherein two stacked sub-layers with different refractive indices are arranged on the light-emitting functional layer. The grooves 310 are defined in the first sub-layer 31 with a low refractive index, and the second sub-layer 32 with a high refractive index is partially within the grooves 310 to fill the grooves 310. Referring to a light path indicated by the right arrow in FIG. 2, in the case that light is obliquely incident from the light-emitting functional layer 20 to an interface between a side wall of the groove 310 and the second sub-layer 32, reflection occurs because the light is incident from the second sub-layer 32 having a high refractive index to the first sub-layer 32 having a low refractive index. In this way, an exiting direction of the light obliquely exiting is changed, such that the light is capable of exiting from a light-exiting surface of the display panel upon being reflected at the interface.

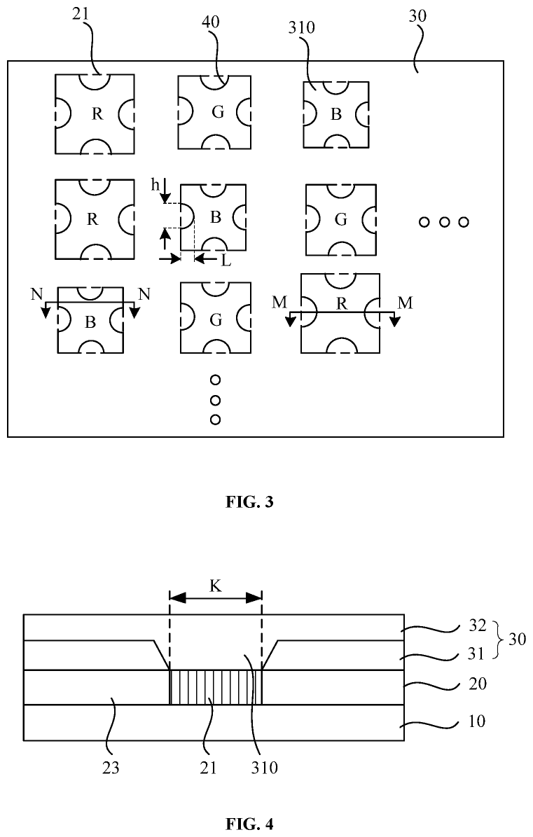

FIG. 3 is a diagram of a projection relation between a first sub-layer and a light-emitting unit according to some embodiments of the present disclosure. As illustrated in FIG. 3, each of the grooves 310 is opposite to one of the plurality of light-emitting units 21 (referring to the dotted line in FIG. 3). At least a portion of an outer profile of an orthographic projection of the groove 310 on the bearing surface (referring to the solid line in FIG. 3) is within an orthographic of the corresponding light-emitting unit 21 on the bearing surface (referring to the dashed line in FIG. 3). The orthographic projection of the light-emitting unit 21 on the bearing surface herein is an orthographic projection of the opening of the pixel-definition layer 23 in the light-emitting functional layer 20.

In some embodiments, as illustrated in FIG. 2 and FIG. 3, a protrusion 40 is formed on the side wall of at least one of the plurality of grooves 310, protruding toward a center of the groove 310.

FIG. 4 is a sectional schematic diagram of a display panel according to some embodiments of the present disclosure. The section illustrated in FIG. 4 is the sectional schematic diagram illustrated along a line NN in FIG. 3. As illustrated in FIG. 4, in a region, where the protrusion 40 is not formed, of the groove 310, in a direction of the section line NN, a width K of the groove of the first sub-layer 31 is not less than a length of the light-emitting unit 21.

FIG. 2 is a sectional schematic diagram illustrated along a line MM in FIG. 4. As illustrated in FIG. 2, in a region, where the protrusion 40 is formed, of the groove 310, in a direction of the cross-section line MM, the width of the groove of the first sub-layer 31 is less than the length of the light-emitting unit 21, such that a portion of the outer profile of the orthographic projection of the groove 310 on the bearing surface is within the orthographic projection of the corresponding light-emitting unit 21 on the bearing surface.

In the above embodiments, a portion of the outer profile of the orthographic projection of the groove 310 is within the orthographic projection of the light-emitting unit 21. That is, a portion of the first sub-layer 31 is opposite to the light-emitting unit 21, such that a portion of the light emitted from the light-emitting unit opposite to this portion of the first sub-layer 31 (referring to a light path indicated by the left arrow in FIG. 2), is capable of entering the first sub-layer 31 having a low refractive index corresponding to this portion. When the light enters the second sub-layer 32 having a high refractive index from the first sub-layer 31 having a low refractive index, the light is refracted, and a refraction angle of the light is caused to be smaller than an incident angle of the light, such that a portion of light emitted from an edge position of the light-emitting unit 21 toward a direction away from a center of the light-emitting unit approaches a direction toward the center of the light-emitting unit. In this way, the light forwardly exiting is increased, and thus a light-exiting efficiency of the display panel is improved.

In some embodiments, the width of the groove of the first sub-layer is less than or equal to the length of the light-emitting unit, such that the outer profile of the orthographic projection of the groove on the bearing surface is entirely within the orthographic projection of the corresponding light-emitting unit on the bearing surface.

The light-emitting unit 21 includes an anode layer, a light-emitting layer, and a cathode layer successively stacked.

In some embodiments, the light-emitting layer includes a hole transport layer (HTL), a hole injection layer (HIL), an electron transport layer (ETL), an electron injection layer (EIL), a hole block layer (HBL), an electron block layer (EBL) and a luminescent material layer. The EIL, the ETL, the HBL, the luminescent material layer, the HTL, the HIL, and the EBL are successively stacked.

In some embodiments, the cathode layer is a transparent conductive layer, and the anode layer is a transparent conductive layer or a metal layer.

In some embodiments, the transparent conductive layer is an indium tin oxide (ITO) layer and an indium zinc oxide (IZO) layer.

In some embodiments, the metal layer is a metal layer such as Mg, Al, Au, Pt, Cu, and the like. The metal layer is a single metal layer or a stack of at least two metal layers.

The driver backplane 10 includes a base substrate and a plurality of driver circuits, and the plurality of driver circuits are arranged in arrays on the base substrate. Each of the driver circuits is connected to a corresponding one of the light-emitting units 21. In some embodiments, the driver circuit is electrically connected to the anode layer of the light-emitting unit 21. In this way, the light-emitting unit 21 emits light driven by the connected driver circuit

In some embodiments, the driver backplane 10 is a thin film transistor (TFT) substrate, and each of the driver circuits on the driver backplane 10 includes at least 2 TFTs for controlling the connected light-emitting units 21 to emit light.

In some embodiments, the driver circuit includes an active layer, a gate insulator layer, a gate layer, an interlayer dielectric layer, and a source-drain layer that are successively stacked on the base substrate. The light-emitting unit 21 is connected to the source-drain layer of the corresponding driver circuit.

In some embodiments, the base substrate is made of glass, quartz, or plastic; the active layer is made of amorphous silicon, polycrystalline silicon, or a metal-oxide-semiconductor; the gate insulator layer is made of silicon oxide, silicon nitride, or silicon oxynitride; the gate layer is made of a single-layered metal film, such as molybdenum, copper, or titanium, or a multilayered metal film, such as molybdenum/aluminum/molybdenum or titanium/aluminum/titanium; the interlayer dielectric layer is made of silicon oxide or silicon nitride; and the source-drain layer is made of a single-layered metal film, such as aluminum, molybdenum, copper, or titanium, or a multilayered metal film, such as molybdenum/aluminum/molybdenum or titanium/aluminum/titanium.

In some embodiments, in the case that the active layer of each TFT of the driver backplane is made of polysilicon, the driver backplane is a low-temperature poly-silicon (LTPS) driver backplane.

In some embodiments, in the case that the active layer of a portion of the TFTs of the driver backplane is made of polysilicon, and the active layer of the other portion of that is made of metal oxide, the driver backplane is a low-temperature polycrystalline oxide (LTPO) driver backplane.

It should be noted that only the structure of the TFT substrate having a single-layered gate metal layer is given in the above embodiments, and the TFT substrate has a variety of structures such as a double-layered gate metal layer, which is not limited herein.

In some embodiments, as illustrated in FIG. 3, the grooves 310 are in one-to-one correspondence to the light-emitting units 21. In other embodiments, the number of grooves 310 is less than the number of light-emitting units 21, with each of the grooves 310 having a light-emitting unit 21 corresponding thereto, and some of the light-emitting units 21 having no grooves 310 corresponding thereto.

In some embodiments, the groove is in any shape, such as a rectangle, a circle, an ellipse, or a polygon, and the grooves are arranged in any manner.

In some embodiments, the light-emitting unit includes light-emitting units of multiple colors, and dimensions of the light-emitting units of different colors are different, and accordingly, dimensions of the grooves 310 corresponding to the light-emitting units are different.

In some embodiments, an area of a red light-emitting unit R is larger than an area of a green light-emitting unit G, and the area of the green light-emitting unit G is larger than an area of a blue light-emitting unit B. An area of the groove 310 corresponding to the red light-emitting unit R is also larger than an area of the groove 310 corresponding to the green light-emitting unit G, and the area of the groove 310 corresponding to the green light-emitting unit G is also larger than an area of the groove 310 corresponding to the blue light-emitting unit B.

In some embodiments, the first sub-layer 31 is a transparent optical material layer or an ink material layer, and the second sub-layer 32 is a transparent optical material layer or an ink material layer.

The transparent optical material layer is a polyimide-based resin layer or an acrylic material layer, and the ink material layer is an acrylic material layer or an epoxy-based material layer.

It should be noted that the transmittance of the transparent optical material layer is not always 100%, and in some embodiments, the transmittance of the transparent optical material layer ranges from 50% to 99%, which is not limited herein.

In some embodiments, as illustrated in FIG. 2, the groove 310 has a first opening 311 and a second opening 312. The first opening 311 is disposed on a side, proximal to the driver backplane 10, of the first sub-layer 31, and the second opening 312 is disposed on a side, distal from the driver backplane 10, of the first sub-layer 31. An orthographic projection of the first opening 311 on the bearing surface is within an orthographic projection of the second opening 312 on the bearing surface. That is, the opening, proximal to the driver backplane 10, of the groove 310 has a smaller area than the opening distal from the driver backplane 10.

In some embodiments, as illustrated in FIG. 2, the side wall of the groove 310 is planar. That is, the side wall of the groove 310 is inclined with respect to the driver backplane 10.

In this way, in the case that the light is obliquely incident from the light-emitting unit 21 to the interface between the side wall of the groove 310 and the second sub-layer 32, because the light is incident from the second sub-layer 32 having a high refractive index to the first sub-layer 31 having a low refractive index, the light is reflected at the interface, such that the exiting angle of the light obliquely exiting is changed. Because the side wall of the groove 310 is inclined, the exiting direction of the reflected light is more likely to tend to a direction perpendicular to the light-exiting surface of the display panel after the light obliquely exiting is reflected by the side wall of the groove 310, such that more light is capable of forwardly exiting.

In some embodiments, as illustrated in FIG. 2, an included angle α between the side wall of the groove 310 and the driver backplane 10 ranges from 40° to 80°.

By limiting the included angle between the side wall of the groove 310 and the driver backplane 10 to the above angular range, the inclination angle of the side wall is prevented from being too large or too small, otherwise, the exiting direction of the light fails to be controlled in the direction perpendicular to the light-exiting surface of the display panel.

In some embodiments, the included angle between the side wall of the groove 310 and the driver backplane 10 is 60°. By defining the inclination angle of the side wall of the groove 310 as this angle, an included angle between the light and the side wall of the groove is within a specific range when a portion of the light is incident to the side wall of the groove, such that the light is allowed to totally reflected, and thus the light-exiting efficiency is improved, and the exiting direction of the most of the light is adjusted to be the direction perpendicular to the light-exiting surface of the display panel, which increases a forward light-exiting efficiency.

The total reflection occurs in the case that the included angle θ between the light and the side wall of the groove is less than or equal to 90−arcsin (n2/n1). n2 represents the refractive index of the first sub-layer, and n1 represents the refractive index of the second sub-layer.

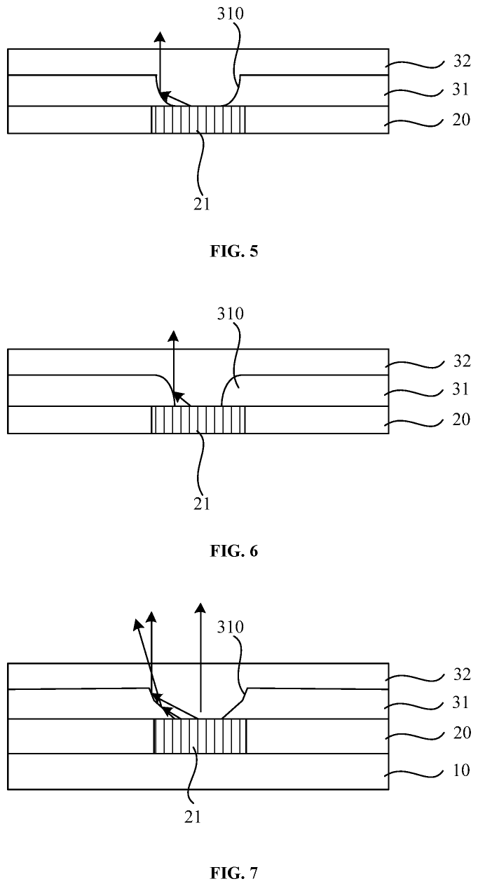

In some embodiments, FIG. 5 is a schematic structural diagram of a light-extraction layer according to some embodiments of the present disclosure. As illustrated in FIG. 5, the side wall of the groove 310 is a curved surface, and the side wall of the groove 310 is recessed along a direction away from the center of the groove 310.

In some embodiments, as illustrated in FIG. 5, the side wall of the groove 310 is an arc surface.

In some embodiments, FIG. 6 is a schematic structural diagram of a light-extraction layer according to some embodiments of the present disclosure. As illustrated in FIG. 6, the side wall of the groove 310 is a curved surface, and the side wall of the groove 310 protrudes toward the center of the groove 310.

In some embodiments, the side wall of the groove 310 is an arc surface, as illustrated in FIG. 6.

By defining the side wall of the groove 310 as the arc surface, after the light obliquely exiting is reflected by the arc surface, the exiting direction of the reflected light is also caused to tend to the direction perpendicular to the exiting surface of the display panel, such that more light is capable of forwardly exiting.

In some embodiments, the side wall of the groove 310 includes a plurality of planar surfaces successively connected between the first opening and the second opening, and an included angle is present between the connected two planar surfaces.

In some embodiments, FIG. 7 is a schematic structural diagram of a light-extraction layer according to some embodiments of the present disclosure. As illustrated in FIG. 7, the side walls of the groove are two connected planar surfaces, and the included angle between the connected two planar surfaces is obtuse.

By defining the side walls of the groove 310 as two connected planes, the light incident to the side walls of the groove at the same angle is capable of exiting from the display panel at different angles, such that a light-exiting area of the light-emitting unit is increased.

It should be noted that in other embodiments, the side walls of the groove 310 are other structures, as long as the light is capable of exiting along the direction perpendicular to the display panel after being reflected by the side wall of the groove 310, which is not limited herein.

In some embodiments, at least a portion of an orthographic projection of the protrusion 40 on the bearing surface is within the orthographic projection of the light-emitting unit 21 on the bearing surface, as illustrated in FIG. 2 and FIG. 3.

A surface, facing the light-emitting unit 21, of the protrusion 40 is in contact with a side surface of the light-emitting unit 21. That is, a side surface, proximal to the light-emitting unit 21, of the protrusion 40 is in the same plane as the side surface of the light-emitting unit 21.

A portion of the surface of the protrusion 40 and a side surface, proximal to the light-emitting unit 21, of the first sub-layer 31 are both in contact with the same surface of the same film layer. In some embodiments, in the case that the first sub-layer 31 is directly disposed on the light-emitting functional layer 20, a portion of the surface of the protrusion 40 is in contact with a side surface, proximal to the first sub-layer, of the light-emitting unit 21.

In some embodiments, the protrusion 40 protrudes toward the center of the groove 310, such that the orthographic projection of the protrusion 40 on the bearing surface is within the orthographic projection of the corresponding light-emitting unit 21 on the bearing surface.

In the above embodiments, compared to a side wall without the protrusion 40, by forming the protrusions 40 on the side wall of the groove 310, a reflective area of the side wall of the groove 310 is increased, such that the forward light-exiting efficiency is further increased. At the same time, the protrusion 40 is opposite to the light-emitting unit 21, such that after a portion, opposite to the protrusion 40, of the light-emitting unit 21 emits light, the light is directly incident to the first sub-layer 31 having a low refractive index, and thus the light is refracted when it then enters the second sub-layer 32 having a high refractive index from the first sub-layer 31 having a low refractive index. Referring to the light path illustrated in FIG. 2, by causing a portion of the light to exit toward a periphery of the display panel, more light is capable of exiting from the display panel, and the light is capable of uniformly exiting from the display panel at various locations, such that the light-exiting effect of the entire surface of the display panel is improved.

In some embodiments, at least a portion of the orthographic projection of the protrusion 40 on the bearing surface being within the orthographic projection of the light-emitting unit 21 on the bearing surface includes the following two embodiments.

In a first embodiment, referring to FIG. 3, a portion, except for the protrusion 40, of the outer profile of the orthographic projection of the groove 310 on the bearing surface coincides with the outer profile of the orthographic projection of the corresponding light-emitting unit 21 on the bearing surface, whereupon the orthographic projection of the protrusion 40 on the bearing surface is completely within the orthographic projection of the corresponding light-emitting unit 21 on the bearing surface.

In a second embodiment, a portion of the outer profile of the orthographic projection of the groove on the bearing surface, except for the protrusion 40 encircles the outer profile of the orthographic projection of the corresponding light-emitting unit on the bearing surface. That is, the orthographic projection of the light-emitting unit on the bearing surface is within the portion of the outer profile of the orthographic projection of the corresponding groove on the bearing surface except for the protrusion. In this case, only a portion of the orthographic projection of the protrusion on the bearing surface is within the orthographic projection of the corresponding light-emitting unit on the bearing surface.

In some embodiments, as illustrated in FIG. 3, a maximum length L of the protrusion 40 ranges from 1 μm to 3 μm, and a maximum width h of that ranges from 1 μm to 5 μm.

The length of the protrusion is a maximum distance from a point, of an outer wall surface of the protrusion located in a section, parallel to the bearing surface, of the protrusion, to the side wall of the groove.

The width of the protrusion is a maximum distance along a direction perpendicular to a lengthwise direction of the protrusion in the section, parallel to the bearing surface, of the protrusion.

In some embodiments, a shape of the section, parallel to the bearing surface, of the protrusion 40 includes an arc.

In some embodiments, the section of the protrusion 40 parallel to the bearing surface is in the shape of a semi-circle or a semi-ellipse.

It should be noted that the section of the protrusion 40 parallel to the bearing surface is in other shapes, e.g., a major arc or a minor arc, which is not limited herein.

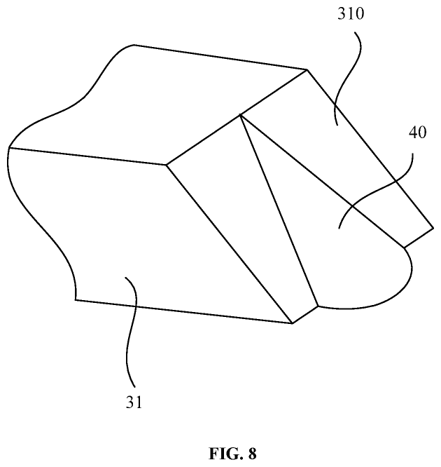

In some embodiments, FIG. 8 is a partially schematic structural diagram of a first sub-layer according to some embodiments of the present disclosure. As illustrated in FIG. 8, the outer wall surface of the protrusion 40 is a conical surface, and a larger-sized end of the protrusion 40 is coplanar with the side surface, proximal to the light-emitting unit 21, of the first sub-layer 31. As illustrated in FIG. 2, the section of the protrusion 40 parallel to the bearing surface is in the shape of a semi-circle.

The outer wall surface of the protrusion 40 is a surface, in contact with the second sub-layer 32, of the protrusion 40.

By defining the protrusion 40 to be in the shape of a cone, in one aspect, the light emitted from the portion of the light-emitting unit 21 opposite to the protrusion 40 is directly incident to the first sub-layer 31 having a low refractive index, such that the light is refracted at the interface of the first sub-layer 31 and the second sub-layer 32, and thus part of the light is caused to exit toward the periphery of the display panel; and in another aspect, the outer wall surface of the protrusion 40 is a conical surface, and thus compared with an inclined surface, after the light incident from the second sub-layer 32 in various directions toward the first sub-layer 32 is reflected by the conical surface, the majority of the light is capable of exiting from the light-extraction layer at a similar exiting angle, such that the light incident to the first sub-layer 31 in various directions is adjusted to be in the direction perpendicular to the light-exiting surface of the display panel.

In some embodiments, as illustrated in FIG. 3, a maximum radius of a section, parallel to the driver backplane 10, of the protrusion 40 ranges from 1 μm to 3 μm.

By defining the radius of the protrusion 40 to be within the above range, in one aspect, the size of the protrusion 40 is prevented from being too large, otherwise, the size of the groove 310 is decreased, and the amount of light forwardly exiting is reduced; and in another aspect, the size of the protrusion 40 is prevented from being too small, otherwise, the forward light-exiting efficiency fails to be effectively improved.

In some embodiments, as illustrated in FIG. 3, the maximum radius of the protrusion 40 ranges from 1 μm to 2 μm. The maximum radius of the protrusion 40 is a radius of a side surface, toward an end of the driver backplane 10, of the protrusion 40. In some embodiments, the maximum radius of the protrusion 40 is 2 μm.

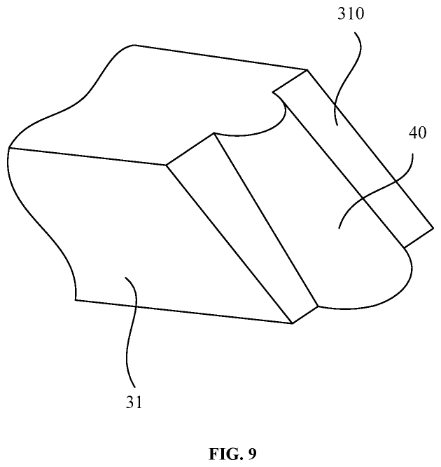

FIG. 9 is a partially schematic structural diagram of another first sub-layer according to some embodiments of the present disclosure. As illustrated in FIG. 9, the outer wall surface of the protrusion 40 is a curved side surface of a frustum cone, and the larger-sized end of the protrusion 40 is coplanar with the side surface, proximal to the light-emitting unit 21, of the first sub-layer 31.

Because the protrusion 40 is in the shape of a frustum cone, compared to the cone-shaped protrusion 40, the outer wall surface of the protrusion 40 in the shape of a frustum cone has a larger area, which provides a larger area for light reflection, and thus the light incident to the first sub-layer 31 in various directions is adjusted to be in the direction perpendicular to the light-exiting surface of the display panel.

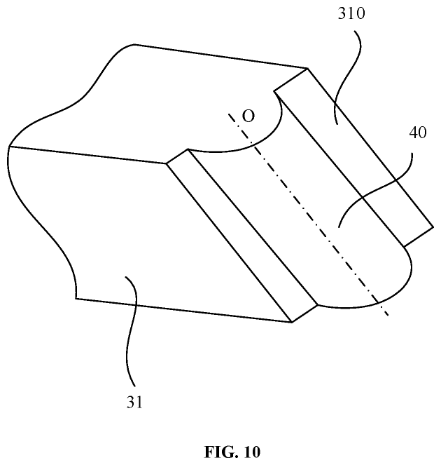

FIG. 10 is a partially schematic structural diagram of still another first sub-layer according to some embodiments of the present disclosure. As illustrated in FIG. 10, the outer wall surface of the protrusion 40 is a cylindrical surface, and a straight generatrix of the cylindrical surface is parallel to the side wall of the groove 310.

By defining the protrusion 40 to be in the shape of a cylinder, in one aspect, the light emitted from the portion of the light-emitting unit 21 opposite to the protrusion 40 is directly incident to the first sub-layer 31 having a low refractive index, such that the light is refracted at the interface of the first sub-layer 31 and the second sub-layer 32, and thus part of the light is caused to exit toward the periphery of the display panel; and in another aspect, the outer wall surface of the protrusion 40 is a cylindrical surface, and thus compared to an inclined surface, the light incident from the second sub-layer 32 in various directions to the first sub-layer 32 is well reflected by the outer wall surface, such that the light incident to the first sub-layer 31 in various directions is adjusted to be in the direction perpendicular to the light-exiting surface of the display panel.

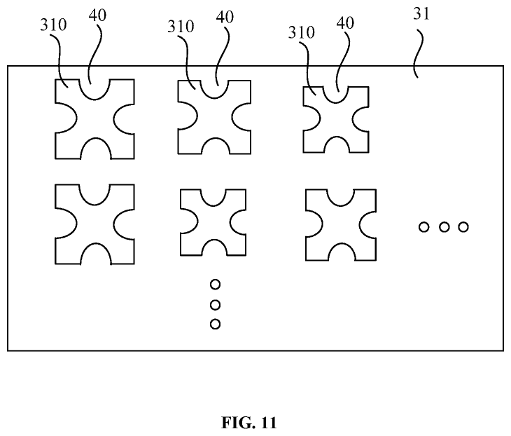

FIG. 11 is a planar schematic diagram of a first sub-layer according to some embodiments of the present disclosure. FIG. 11 is a planar schematic diagram of the first sub-layer illustrated in FIG. 10. As illustrated in FIG. 11, the protrusion 40 has a semi-elliptical section in the direction parallel to the driver backplane 10. Compared to defining the protrusion 40 as a cone, the cylindrical protrusion 40 of the same size (radius) has a larger area opposite to the light-emitting unit 21, thereby more light is allowed to be directly incident to the first sub-layer 31, such that more light is allowed to exit toward the periphery of the display panel. In this way, the light is capable of uniformly exiting from the display panel at various locations, such that the whole surface light-exiting effect of the display panel is improved.

In some embodiments, the protrusion 40 is in the shape of a cylinder, and a radius of the cylindrical protrusion 40 does not exceed 3 μm. In some embodiments, the radius of the cylindrical protrusion 40 is 2 μm.

By defining the radius of the protrusion 40 to be within the above range, in one aspect, the size of the protrusion 40 is prevented from being too large, otherwise, the size of the groove 310 is decreased, and the amount of light forwardly exiting is reduced; and in another aspect, and the size of the protrusion 40 is prevented from being too small, otherwise, the forward light-exiting efficiency fails to be effectively improved.

In some embodiments, as illustrated in FIG. 3, a plurality of the protrusions 40 are provided, and the plurality of protrusions 40 are spaced apart around a geometric center of the groove 310.

By forming the plurality of protrusions 40 on the side wall of the groove 310, the area of the protrusion 40 opposite to the light-emitting unit 21 is increased, such that more light is allowed to be directly incident to the first sub-layer 31, and thus more light is allowed to exit toward the periphery of the display panel, and the whole surface light-exiting effect of the display panel is improved.

In some embodiments, the groove 310 has a plurality of side walls that are successively end to end connected, and at most one protrusion 40 is formed on each of the side walls of the groove 310.

In some embodiments, as illustrated in FIG. 3, the groove 310 includes four side walls successively end to end connected with adjacent two side walls being perpendicular. One protrusion 40 is formed on each of the side walls of each groove 310.

In this way, each of the side walls of the groove 310 allows some of the light to be directly incident to the first sub-layer, such that light at each of the side walls exits toward the periphery of the display panel, and thus the whole surface light-exiting effect of the display panel is improved.

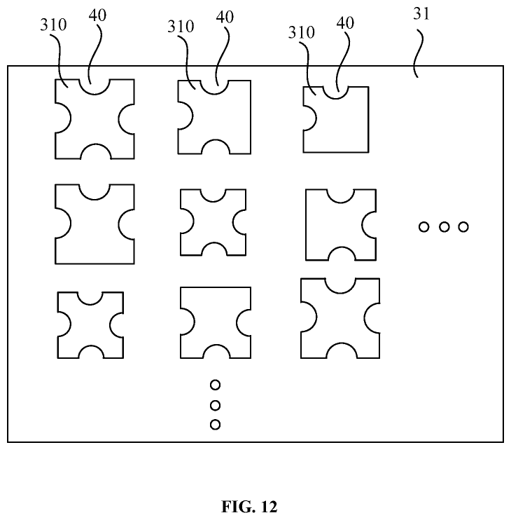

In some embodiments, FIG. 12 is a planar schematic diagram of a first sub-layer according to some embodiments of the present disclosure. As illustrated in FIG. 12, the groove 310 includes four side walls that are successively end to end connected, and adjacent two side walls are perpendicular. Some of the side walls of a portion of the grooves 310 are not provided with the protrusions 40, while the side walls of the other portion of the grooves 310 are respectively provided with the protrusions 40, such that the whole surface light-exiting effect of the display panel is improved, and the forward light-exiting efficiency is ensured.

It should be noted that in some embodiments, some of the grooves 310 are not provided with the protrusions 40 on the side walls, as long as the whole-surface light-exiting effect of the display panel satisfies the requirement, which is not limited herein.

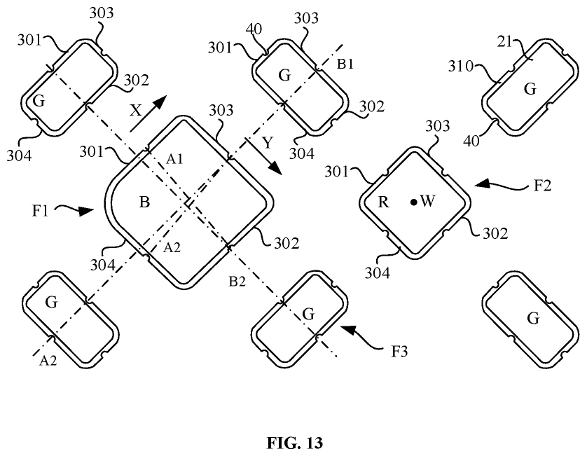

FIG. 13 is a distribution schematic diagram of light-emitting units according to some embodiments of the present disclosure. As illustrated in FIG. 13, the orthographic projection of the light-emitting unit 21 on the bearing surface is within the outer profile of the orthographic projection of the groove 310 on the bearing surface.

In some embodiments, as illustrated in FIG. 13, a protrusion is formed on the side wall of at least one of the plurality of grooves 310. The protrusion 40 protrudes toward the center of the groove 310, and the orthographic projection of the protrusion 40 on the bearing surface is outside the orthographic projection of the light-emitting unit 21 on the bearing surface. In this way, all of the light emitted by the light-emitting unit 21 is reflected by the side wall of the groove 310, such that the light forwardly exiting from the display panel is increased.

In some embodiments, the plurality of light-emitting units 21 are arranged in a matrix in a first direction X and a second direction Y, as illustrated in FIG. 13.

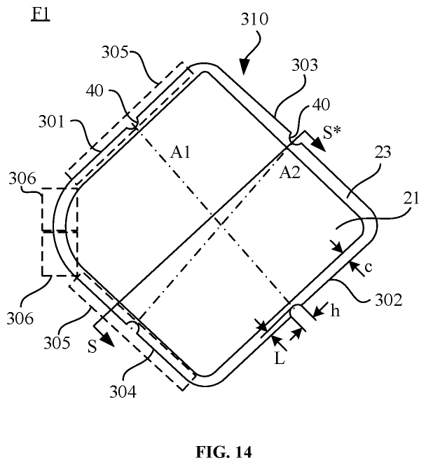

FIG. 14 is a schematic structural diagram of a light-emitting unit according to some embodiments of the present disclosure. As illustrated in FIG. 14, the plurality of light-emitting units 21 include a first light-emitting unit F1. The groove 310 corresponding to the first light-emitting unit F1 includes a first side wall 301, a third side wall 303, a second side wall 302, and a fourth side wall 304 that are successively connected, and one protrusion 40 is formed on each of the side walls of the groove 310.

The first side wall 301 and the second side wall 302 are opposite to each other, and the third side wall 303 and the fourth side wall 304 are opposite to each other.

In some embodiments, as illustrated in FIG. 14, a line connecting a geometric center of the protrusion 40 of the first side wall 301 to a geometric center of the protrusion 40 of the second side wall 302 is a first connection line A1, and the first connection line A1 is intersected with the third side wall 303 or the fourth side wall 304.

The first connection line A1 being intersected with the third side wall 303 refers to the first connection line A1 being intersected with an extension line of a side edge, proximal to the first light-emitting unit, of the third side wall 303. The first connection line A1 being intersected with the fourth side wall 304 refers to the first connection line A1 being intersected with an extension line of a side edge, proximal to the first light-emitting unit, of the fourth side wall 304.

In some embodiments, as illustrated in FIG. 14, a line connecting a geometric center of the protrusion 40 of the third side wall 303 to a geometric center of the protrusion 40 of the fourth side wall 304 is a second connection line A2, and the second connection line A2 is intersected with the first side wall 301 or the second side wall 302.

The second connection line A2 being intersected with the first side wall 301 refers to the second connection line A2 being intersected with an extension line of a side edge, proximal to the first light-emitting unit, of the first side wall 301. The second connection line A2 being intersected with the second side wall 302 refers to the second connection line A2 being intersected with an extension line of a side edge, proximal to the first light-emitting unit, of the second side wall 302.

In some embodiments, each of the side edges, proximal to the first light-emitting unit, of the first side wall 301, the second side wall 302, the third side wall 303, and the fourth side wall 304 includes a straight line segment 305.

The side edge, proximal to the first light-emitting unit, of at least one of the first side wall 301, the second side wall 302, the third side wall 303, and the fourth side wall 304 further includes a curved line segment 306. The curved line segment 306 is connected to an end of the straight line segment 305 of the side edge on which the curved line segment 306 is disposed. The protrusions 40 on the first side wall 301, the second side wall 302, the third side wall 303, and the fourth side wall 304 are respectively disposed at midpoints of the corresponding straight line segments 305.

In some embodiments, as illustrated in FIG. 14, each of the first side wall 301 and the fourth side wall 304 of the first light-emitting unit includes one straight line segment and one curved line segment. The curved line segment of the first side wall 301 is connected to the curved line segment of the fourth side wall 304, with the connected two curved line segments forming a fillet. That is, each of the side edges, proximal to the first light-emitting unit, of the first side wall 301 and the fourth side wall 304 includes the straight line segment 305 and the curved line segments 306. The curved line segment 306 of the first side wall 301 is connected to the curved line segment 306 of the fourth side wall 304 so as to form the fillet at the junction of the first side wall 301 and the fourth side wall 304.

As illustrated in FIG. 14, the protrusion 40 on the first side wall 301 is disposed at the midpoint of the straight line segment 305 and the protrusion 40 on the fourth side wall 304 is disposed at the midpoint of the straight line segment 305.

In some embodiments, as illustrated in FIG. 14, in the first light-emitting unit, the protrusion of the third side wall is disposed at the midpoint of the straight line segment. That is, a distance from the protrusion of the third side wall to the first side wall or the second side wall is equal to one-half of a spacing between the first side wall and the second side wall.

In some embodiments, as illustrated in FIG. 14, in the first light-emitting unit, the protrusion of the second side wall is disposed at the midpoint of the straight line segment. That is, a distance from the protrusion of the second side wall to the third side wall or the fourth side wall is equal to one-half of a spacing between the third side wall and the fourth side wall.

In the above embodiments, both the second side wall and the third side wall include only straight line segments, and the protrusions on the second side wall and the fourth side wall are disposed at the midpoints of the straight line segments. In this way, the protrusion on each side wall is arranged at the midpoint of the straight line segment, which facilitates color cast balance.

As illustrated in FIG. 13, the first connection line A1 is intersected with both the first direction X and the second direction Y; and/or the second connection line A2 is intersected with both the first direction X and the second direction Y.

By arranging the light-emitting units in such a matrix, the arrangement position and spacing of the plurality of light-emitting units are reasonably controlled, and thus the light-emitting effect of the display panel is ensured.

In some embodiments, as illustrated in FIG. 13, the plurality of light-emitting units further include a second light-emitting unit F2 and a third light-emitting unit F3.

As illustrated in FIG. 13, each of the second light-emitting unit F2 and the third light-emitting unit F3 includes four side walls successively connected and the protrusions 40 respectively disposed on the four side walls.

The second light-emitting unit F2 and the third light-emitting unit F3 are similar to the first light-emitting unit F1, each of which likewise includes a first side wall 301, a third side wall 303, a second side wall 302, and a fourth side wall 304 that are successively connected and one protrusion 40 is formed on each of the side walls.

As illustrated in FIG. 13, two opposite protrusions 40 on the second light-emitting unit F2 are arranged along a first straight line B1 or a second straight line B2, and two opposite protrusions 40 on the third light-emitting unit F3 are arranged along the first straight line B1 or the second straight line B2. The first straight line B1 is parallel to the first direction X, and the second straight line B2 is parallel to the second direction Y.

As illustrated in FIG. 13, the first connection line A1 is intersected with the second direction Y, and the second connection line A2 is intersected with the first direction X.

In some embodiments, the first light-emitting unit F1 is a blue light-emitting unit B, the second light-emitting unit F2 is a red light-emitting unit R, and the third light-emitting unit F3 is a green light-emitting unit G.

In FIG. 13, the largest rectangular block is the blue light-emitting unit B, the smallest rectangular block is the green light-emitting unit G, and the rectangular block with an area between the two is the red light-emitting unit R. The blue light-emitting unit B, the red light-emitting unit R, and the green light-emitting unit G are arranged in a matrix along the first direction X and the second direction Y.

As illustrated in FIG. 13, the first connection line A1 of the blue light-emitting unit is intersected with the second direction Y, and the second connection line A2 of the blue light-emitting unit is intersected with the first direction X.

In combination with FIG. 13 and FIG. 14, in the blue light-emitting unit, a fillet is formed in a region where the first side wall 301 and the fourth side wall 304 are connected, and the protrusion 40 is disposed at the midpoint of the straight line segment 305, and thus the protrusion 40 on the first side wall 301 is not disposed at the midpoint of the side edge, and the protrusion 40 on the second side wall 302 is disposed at the midpoint of the side edge, and therefore, the protrusion 40 of the first side wall 301 and the protrusion 40 of the second side wall 302 of the groove 310 are not arranged along the second direction Y. The protrusion 40 on the third side wall 303 is not disposed at the midpoint of the side edge, and the protrusion 40 on the fourth side wall 304 is disposed at the midpoint of the side edge, and thus, the protrusion 40 of the third side wall 303 and the protrusion 40 of the fourth side wall 304 of the groove 310 are not arranged along the first direction X either.

In some embodiments, as illustrated in FIG. 14, in the blue light-emitting unit, a fillet is also formed at a position, corresponding to the fillet between the first side wall 301 and the fourth side wall 304, of the pixel-definition layer 23. That is, the fillet is defined between a side wall, corresponding to the first side wall 301 of the groove 310, of the pixel-definition layer 23 and a side wall, corresponding to the fourth side wall 304 of the groove 310, of the pixel-definition layer 23, such that the shape of the pixel-definition layer 23 is consistent with the shape of the light-extraction layer 30, which facilitates the exiting of the light.

As illustrated in FIG. 13, the protrusion of the first side wall 301 and the protrusion of the second side wall 302 of the red light-emitting unit R are arranged along the second straight line B2, and the protrusion of the third side wall 303 and the protrusion of the fourth side wall 304 of the red light-emitting unit R are arranged along the first straight line B1.

In the red light-emitting unit, the side edges of the first side wall 301, the second side wall 302, the third side wall 303, and the fourth side wall 304 are not provided with the curved line segments. Therefore, in the red light-emitting unit, the protrusion 40 of the first side wall 301 and the protrusion 40 of the second side wall 302 of the groove 310 are arranged along the second straight line B2, and the protrusion 40 of the third side wall 303 and the protrusion 40 of the fourth side wall 304 of the groove 310 are arranged along the first straight line B1.

As illustrated in FIG. 13, the protrusion of the first side wall 301 and the protrusion of the second side wall 302 of the green light-emitting unit G are arranged along the second straight line B2, and the protrusion of the third side wall 303 and the protrusion of the fourth side wall 304 of the green light-emitting unit G are arranged along the first straight line B1.

In the green light-emitting unit, the side edges of the first side wall 301, the second side wall 302, the third side wall 303, and the fourth side wall 304 are not provided with the curved line segments. Therefore, in the green light-emitting unit, the protrusion 40 of the first side wall 301 and the protrusion 40 of the second side wall 302 of the groove 310 are arranged along the second straight line B2, and the protrusion 40 of the third side wall 303 and the protrusion 40 of the fourth side wall 304 of the groove 310 are arranged along the first straight line B1.

In some embodiments, as illustrated in FIG. 13 and FIG. 14, each of the first side wall 301 and the fourth side wall 304 of the first light-emitting unit includes one straight line segment 305 and one curved line segment 306. The curved line segment 306 of the first side wall 301 is connected to the curved line segment 306 of the fourth side wall 304.

In some embodiments, as illustrated in FIG. 13, the protrusion 40 on the first side wall 301 of the first light-emitting unit is not overlapped with the second straight line, the protrusion 40 on the fourth side wall 304 of the first light-emitting unit is not overlapped with the first straight line, the protrusion 40 on the second side wall 302 of the first light-emitting unit is on the second straight line, and the protrusion 40 on the third side wall 303 of the first light-emitting unit is on the first straight line.

As illustrated in FIG. 13, the protrusion 40 on the first side wall 301 of the first light-emitting unit is on the second straight line, the protrusion 40 on the fourth side wall 304 of the first light-emitting unit is on the first straight line, the protrusion 40 on the second side wall 302 of the first light-emitting unit is not overlapped with the second straight line, and the protrusion 40 on the third side wall 303 of the first light-emitting unit is not overlapped with the first straight line.

In the above embodiments, in the first light-emitting unit, the protrusion of the second side wall without the fillet is arranged along the same straight line as the protrusions of the second side walls of other light-emitting units; and the protrusion of the third side wall without the fillet is arranged along the same straight line as the protrusions of the third side walls of other light-emitting units. The protrusion of the first side wall having the fillet is not arranged in the same straight line as the protrusions of the first side walls of the other light-emitting units; and the protrusion of the fourth side wall having the fillet is not arranged in the same straight line as the protrusions of the fourth side walls of other light-emitting units.

In some embodiments, as illustrated in FIG. 13, in at least some of the light-emitting units, the geometric centers of the plurality of protrusions 40 are overlapped with the geometric center of the groove 310. One protrusion 40 is formed on each of the side walls of the groove, and the geometric center of the plurality of protrusions 40 as a whole is overlapped with the geometric center of the groove 310.

In some embodiments, as illustrated in FIG. 13, the geometric center of the four protrusions 40 as a whole of the red light-emitting unit R is overlapped with the geometric center W of the groove 310.

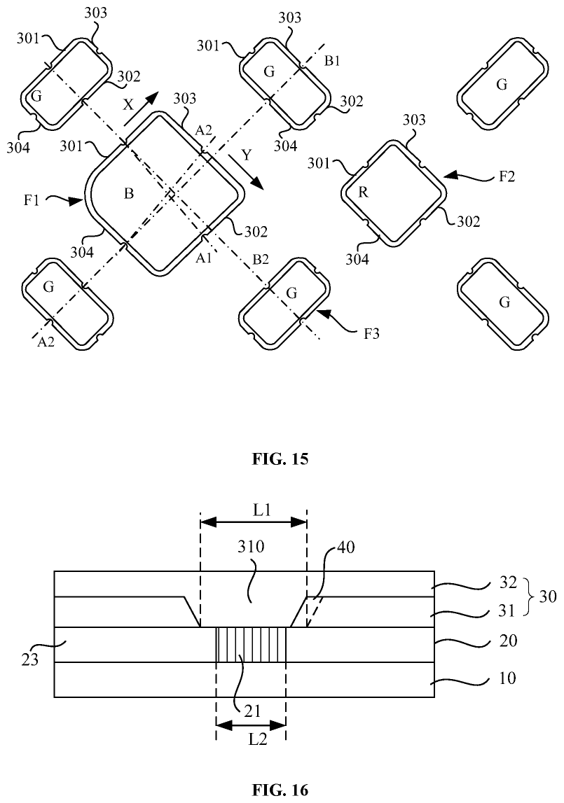

In other embodiments, as illustrated in FIG. 15, the protrusion 40 on the first side wall 301 of the first light-emitting unit is on an extension line of the first connection line A1 of the green light-emitting unit, and the protrusion 40 on the second side wall 302 of the blue light-emitting unit is outside the extension line of the first connection line A1 of the green light-emitting unit.

As illustrated in FIG. 15, the protrusion 40 on the fourth side wall 304 of the first light-emitting unit is on the first straight line B1, and the protrusion 40 on the third side wall 303 of the blue light-emitting unit is outside the first straight line B1.

In the above embodiments, in the first light-emitting unit, the protrusion on the second side wall without the fillet is not arranged in the same straight line as the protrusions on the second side walls of other light-emitting units; and the protrusion on the third side wall without the fillet is not arranged in the same straight line as the protrusions on the third side walls of other light-emitting units. The protrusion of the first side wall having the fillet is arranged along the same straight line as the protrusions of the first side walls of other light-emitting units; and the protrusion of the fourth side wall having the fillet is arranged along the same straight line as the protrusions of the fourth side walls of the other light-emitting units.

It should be noted that both of the above embodiments are exemplified by the junction of the first side wall and the fourth side wall of the first light-emitting unit having the fillet. In other embodiments, at least two of the first light-emitting unit, the second light-emitting unit, and the third light-emitting unit employ the structure of the first light-emitting unit.

In some embodiments, each of the light-emitting units employs the structure of the first light-emitting unit. That is, the first light-emitting unit, the second light-emitting unit, and the third light-emitting unit have the fillets at the junctions of their first side walls and the fourth side walls.

In some embodiments, the first light-emitting unit and the second light-emitting unit have the same structure. That is, the first light-emitting unit and the second light-emitting unit both have the fillets at the junctions of their first side walls and the fourth side walls.

In some embodiments, the first light-emitting unit and the third light-emitting unit have the same structure. That is, the first light-emitting unit and the third light-emitting unit both have the fillets at the junctions of their first side walls and the fourth side walls.

It should be noted that in the case that the orthographic projection of the protrusion 40 on the bearing surface is outside the orthographic projection of the light-emitting unit 21 on the bearing surface, the shape and size of the protrusion 40 are referred to the embodiments illustrated in FIG. 4 to FIG. 11.

In some embodiments, as illustrated in FIG. 14, the maximum width h of the protrusion 40 ranges from 1 μm to 5 μm, and the maximum length L of the protrusion 40 ranges from 1 μm to 3 μm. A widthwise direction and a lengthwise direction of the protrusion 40 are perpendicular, and both the widthwise direction and the lengthwise direction of the protrusion 40 are parallel to the bearing surface of the driver backplane 10.

In some embodiments, the maximum width h of the protrusion is 1 μm, the maximum length L of the protrusion is 1 μm, and an opening length of the groove of the first sub-layer is the same as an opening length of the pixel-definition layer, such that the protrusion and the light-emitting unit have a portion overlapped with each other. That is, the orthographic projection of the protrusion on the bearing surface is within the orthographic projection of the opening of the pixel-definition layer on the bearing surface. At this time, the power consumption gain of the display panel is maximized.

In some embodiments, a difference between the opening length of the groove 310 of the first sub-layer in the light-extraction layer and the opening length of the pixel-definition layer is ±4 m. That is, the opening length of the groove is larger or smaller than the opening length of the pixel-definition layer, and distances c between the groove 310 and the two side walls that are parallel to each other and nearest to each other in the pixel-definition layer 23 range from 0 to 2 μm.

Using the first sub-layer as an example, the opening length of the groove 310 refers to a distance between two opposite side walls of the groove of the first sub-layer, such as a distance between the first side wall and the second side wall of the groove.

The opening length of the pixel-definition layer is a distance between two opposite side walls of the pixel-definition layer, such as a distance between two side walls, one of which is parallel and proximal to the first side wall and the other is parallel and proximal to the second side wall, of the pixel-definition layer.

FIG. 16 is a sectional schematic diagram of a display panel according to some embodiments of the present disclosure. FIG. 16 illustrates a sectional view taken along an SS* section line in FIG. 14, wherein the left side in FIG. 16 is an S end, and the right side in FIG. 16 is an S* end. As illustrated in FIG. 16, the opening length L1 of the groove 310 of the first sub-layer 31 is greater than the opening length L2 of the pixel-definition layer 23.

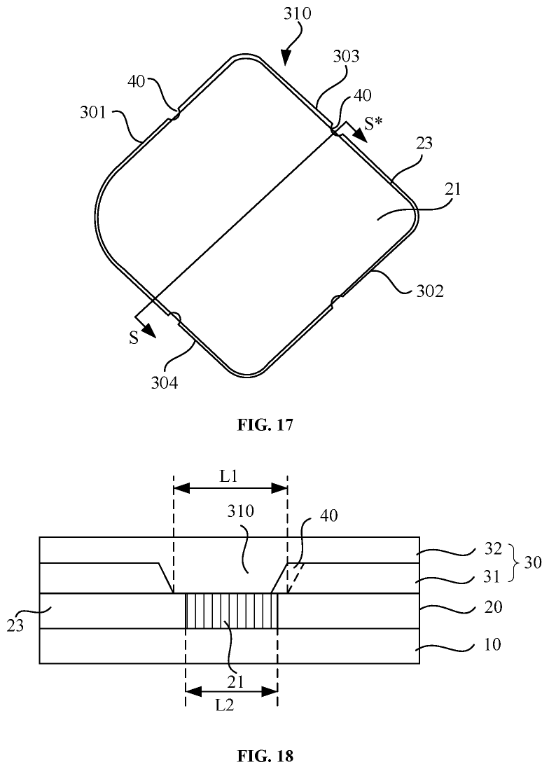

FIG. 17 is a schematic structural diagram of a light-emitting unit according to some embodiments of the present disclosure. A portion region of the protrusion 40 in FIG. 17 is overlapped with the light-emitting unit 21. FIG. 18 is a sectional schematic diagram of a display panel according to some embodiments of the present disclosure. FIG. 18 illustrates a sectional view taken along an SS* section line in FIG. 17. As illustrated in FIG. 18, the opening length L1 of the groove 310 of the first sub-layer 31 is larger than the opening length L2 of the pixel-definition layer 23, and a portion region of the protrusion 40 is overlapped with the light-emitting unit 21.

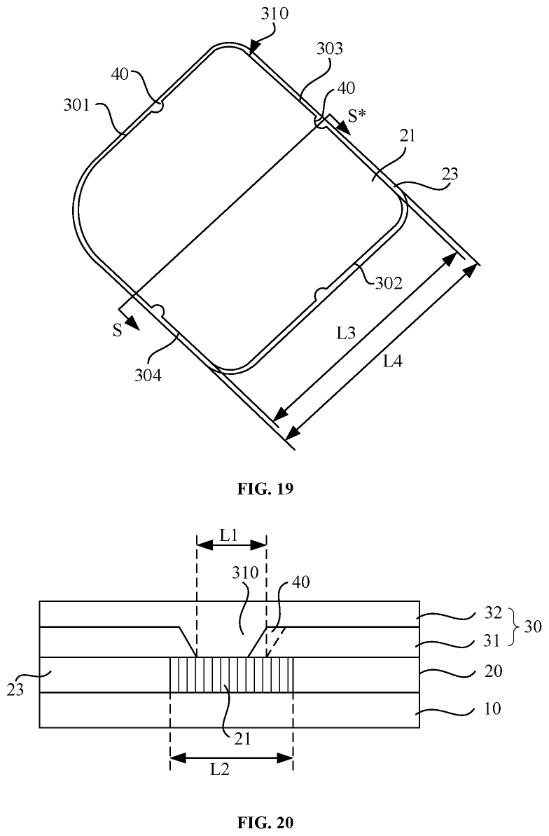

FIG. 19 is a schematic structural diagram of a light-emitting unit according to some embodiments of the present disclosure. The protrusion 40 in FIG. 19 is entirely within the light-emitting unit 21. FIG. 20 is a sectional schematic diagram of a display panel according to some embodiments of the present disclosure. FIG. 20 illustrates a sectional view taken along an SS* section line in FIG. 19. As illustrated in FIG. 20, the opening length L1 of the groove 310 of the first sub-layer 31 is smaller than the opening length L2 of the pixel-definition layer 23.

It should be noted that in the case that a viewing angle of the display panel needs to be adjusted, the opening length of the groove of the first sub-layer and the opening length of the pixel-definition layer are adjusted to cause the opening length of the groove of the first sub-layer to be larger or smaller than the opening length of the pixel-definition layer, and the distances between the two side walls, which are parallel to each other and nearest to each other, in the groove and the pixel-definition layer are controlled to be not greater than 2 μm.

In some embodiments, the opening length of the groove of the first sub-layer is larger than the opening length of the pixel-definition layer, and the opening of the pixel-definition layer is within the opening of the groove of the first sub-layer; and in some embodiments, the opening length of the groove of the first sub-layer is smaller than the opening length of the pixel-definition layer, and the opening of the groove of the first sub-layer is within the opening of the pixel-definition layer. In the two embodiments, the distances between the groove and the two side walls that are parallel to each other and closest to each other in the pixel-definition layer range from 0 to 2 m.

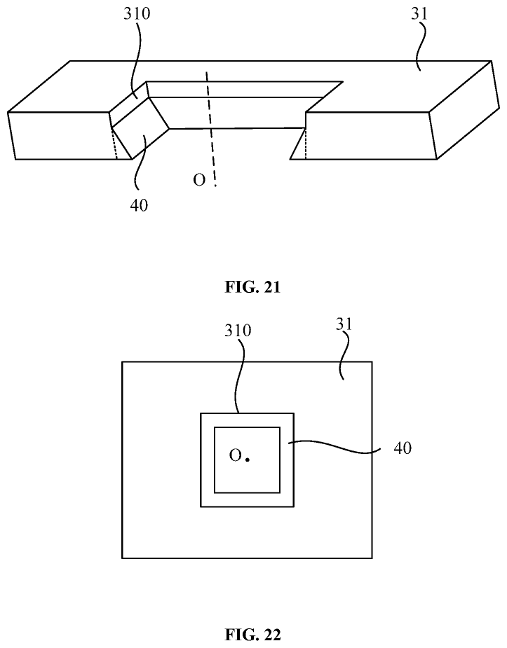

FIG. 21 is a partially schematic structural diagram of a first sub-layer according to some embodiments of the present disclosure. FIG. 22 is a top view of a first sub-layer according to some embodiments of the present disclosure. As illustrated in FIG. 21 and FIG. 22, the protrusion 40 is in the shape of a box, and the geometric center O of the protrusion 40 is the same as the geometric center O of the groove 310.

The shape of a box refers to a symmetrical shape having a bore, such as a square box or a toroid. The geometric center is the most central location of a symmetrical shape. In some embodiments, in the case that the shape is a toroid, the geometric center is a circle center of the toroid.

By defining the protrusion 40 to be in the shape of a box, the area of the protrusion 40 opposite to the light-emitting unit 21 is maximized, such that more light is allowed to be directly incident to the first sub-layer 31, and thus more light is capable of exiting toward the periphery of the display panel. In this way, the whole surface light-exiting effect of the display panel is improved.

In some embodiments, a section of the groove 310 in the direction parallel to the driver backplane 10 and a section of the protrusion 40 in the direction of the driver backplane 10 are in the same shape, such that an outer edge of the protrusion 40 is just connected to the side wall of the groove 310.

In some embodiments, both the section of the groove 310 and the section of the protrusion 40 are circular. That is, the protrusion 40 is in the shape of a toroid.

In some embodiments, the section of the groove 310 and the section of the protrusion 40 are in the shape of a rectangle, as illustrated in FIG. 22.

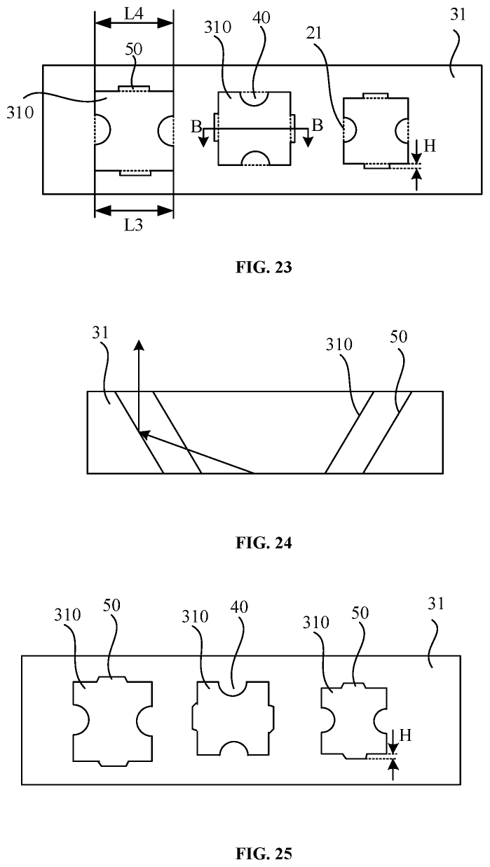

FIG. 23 is a planar schematic diagram of a first sub-layer according to some embodiments of the present disclosure. As illustrated in FIG. 23, a recessed portion 50 is defined in the side wall of the groove 310, and the recessed portion 50 is recessed along a direction away from the geometric center of the groove 310, and the recessed portion 50 is disposed at least in a side surface, proximal to the light-emitting functional layer 20, of the first sub-layer 31.

As illustrated in FIG. 23, at least a portion of an orthographic projection of the recessed portion 50 on the bearing surface is outside the orthographic projection of the corresponding light-emitting unit 21 on the base substrate of the driver backplane 11.

Providing the recessed portion 50 is equivalent to enlarging the size of the groove 310, such that more light emitted from the edge region of the light-emitting units 21 is incident to the recessed portion 50, and thus more light is allowed to be reflected at a surface of the recessed portion 50 and to exit from the light-exiting surface of the display panel. In this way, the forward light-exiting efficiency of the light-emitting unit 21 is improved.

In some embodiments, a recessed depth of the recessed portion 50 is not greater than 5 μm. The recessed depth of the recessed portion 50 is a length of the recessed portion 50 recessed along the direction away from the center of the groove 310 in a direction parallel to the base substrate

By defining the recessed depth of the recessed portion 50 to be within the above range, the recessed depth of the recessed portion 50 is prevented from being too large, otherwise, the amount of light directly incident from the light-emitting unit 21 to the first sub-layer 31 is reduced and the amount of light exiting toward the periphery of the display panel is reduced. In this way, the light exit uniformly from the display panel at various locations.

In some embodiments, the recessed depth of the recessed portion 50 ranges from 1 μm to 3 m. In some embodiments, the recessed depth of the recessed portion 50 is 2 μm.

In some embodiments, a shape of the orthographic projection of the recessed portion 50 on the bearing surface includes at least one of a rectangle, a trapezoid, a triangle, and an arc.

In some embodiments, as illustrated in FIG. 23, the orthographic projection of the recessed portion 50 on the bearing surface is in the shape of a rectangle. A length of the rectangle ranges from 1 μm to 2 μm, and a width of the rectangle, i.e., the recessed depth H of the recessed portion 50, ranges from 1 μm to 3 μm.

FIG. 24 is a sectional view of a first sub-layer according to some embodiments of the present disclosure. FIG. 24 is a sectional view acquired by sectioning along a BB section line in FIG. 23. As illustrated in FIG. 24, the side wall of the groove 310 is an inclined surface, and accordingly, a side wall on which a long side of the rectangle is disposed is an inclined surface, and an inclination angle between the side wall of the groove 310 and the driver backplane 10 is equal to an inclination angle between the side wall on which the long side of the rectangle is disposed and the driver backplane 10.

As illustrated in FIG. 24, by defining the side wall of the groove 310 to be parallel to the side wall, of the recessed portion 50 where the long side of the rectangle is disposed, the light obliquely incident to the side wall of the first sub-layer 31 and the light incident to the side wall where the long side of the rectangle is disposed, of which the incident angles are the same, are capable of exiting from the light-exiting surface of the display panel at the same exiting angle.

In some embodiments, as illustrated in FIG. 25, the orthographic projection of the recessed portion 50 on the bearing surface is in the shape of a trapezoid. A length of the rectangle ranges from 1 μm to 2 μm, and a height of the rectangle, i.e., the recessed depth H of the recessed portion 50, ranges from 1 μm to 3 μm.

In the above embodiments, the side wall of the groove 310 is an inclined surface, and accordingly, the side wall on which an upper base of the trapezoid is disposed is also an inclined surface, and the inclination angle between the side wall of the groove 310 and the driver backplane 10 is equal to an inclination angle between the side wall on which the upper base of the trapezoid is disposed and the driver backplane 10.

By defining the side wall of the groove 310 to be parallel to the side wall where the upper base of the trapezoid is disposed, the light obliquely incident to the side wall of the first sub-layer 31 and the light incident to the side wall where the upper base of the trapezoid is disposed, of which the incident angles are the same, are capable of exiting from the light-exiting surface of the display panel at the same exiting angle.

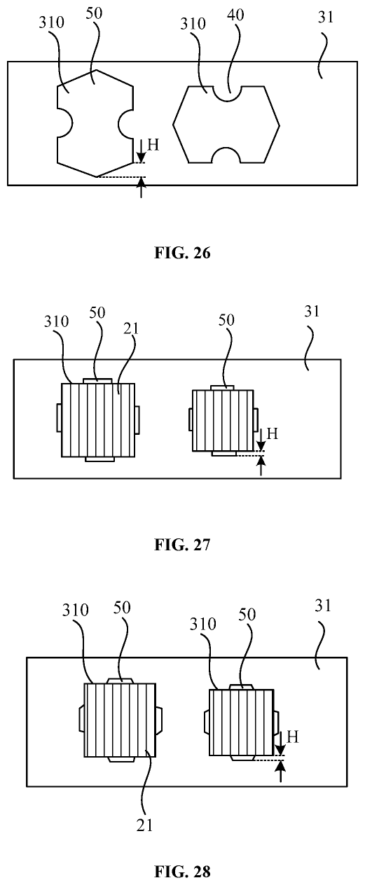

In some embodiments, as illustrated in FIG. 26, the orthographic projection of the recessed portion 50 on the bearing surface is in the shape of a triangle. The triangle is an isosceles triangle. In the direction parallel to the driver backplane 10, a length of a bottom base of the isosceles triangle is equal to the length of the side wall of the groove 310, and a distance from a vertex of the isosceles triangle to the bottom base, i.e., the recessed depth H of the recessed portion 50, ranges from 1 μm to 3 μm.

In the case that the orthographic projection of the recessed portion 50 is in the shape of a triangle, compared to the orthographic projection of the recessed portion 50 being rectangular or trapezoidal, the area of the orthographic projection of the recessed portion 50 on the bearing surface is larger, such that more light is allowed to be reflected at the surface of the recessed portion 50.

FIG. 23 to FIG. 26 illustrate only the case where a difference between an opening length L3 of the groove 310 and an opening length L4 of the pixel-definition layer is zero. At this point, the orthographic projection of the recessed portion 50 on the bearing surface is entirely outside the orthographic projection of the corresponding light-emitting unit on the bearing surface.

In some embodiments, the opening length L3 of the groove 310 is smaller than the opening length L4 of the pixel-definition layer (referring to FIG. 19). In this case, the recessed portion 50 disposed in the side wall of the groove 310 only partially protrudes out of the light-emitting unit 21. That is, a portion of the orthographic projection of the recessed portion 50 on the bearing surface is within the orthographic projection of the corresponding light-emitting unit on the bearing surface, and another the other of the orthographic projection of the recessed portion 50 on the bearing surface is outside the orthographic projection of the corresponding light-emitting unit on the bearing surface.

In other embodiments, the opening length of the groove 310 is larger than the opening length of the pixel-definition layer (referring to FIG. 14 and FIG. 17). In this case, the recessed portion 50 disposed in the side wall of the groove 310 is also entirely outside the orthographic projection of the corresponding light-emitting unit on the bearing surface.

In some embodiments, only the recessed portion is defined in the side wall of the groove. That is, the protrusion is not defined on the side wall of the groove.

FIG. 27 is a planar schematic diagram of a first sub-layer according to some embodiments of the present disclosure. As illustrated in FIG. 27, a recessed portion 50 is defined in the side wall of the groove 310. The recessed portion 50 is recessed along the direction away from a geometric center of the groove 310, and the recessed portion 50 is disposed at least in the side surface, proximal to the light-emitting functional layer, of the first sub-layer 31.

As illustrated in FIG. 27, at least a portion of the orthographic projection of the recessed portion 50 on the bearing surface is outside of the orthographic positive projection of the corresponding light-emitting unit 21 on the base substrate of the driver backplane 11.

In some embodiments, the orthographic projection of the recessed portion on the base substrate is entirely outside the orthographic projection of the corresponding light-emitting unit on the base substrate.

In other embodiments, a portion of the recessed portion is opposite to the light-emitting unit, and the orthographic projection of another portion of the recessed portion that is not opposite to the light-emitting unit on the base substrate is outside the orthographic projection of the corresponding light-emitting unit on the base substrate.

The size of the groove 310 is enlarged by defining the recessed portion 50, such that more light emitted from the edge region of the light-emitting units 21 is incident to the recessed portion 50, and thus more light is allowed to be reflected at the surface of the recessed portion 50 and to exit from the light-exiting surface of the display panel. In this way, the forward light-exiting efficiency of the light-emitting unit 21 is improved.

In some embodiments, the recessed depth H of the recessed portion 50 is not greater than 5 m. The recessed depth of the recessed portion 50 is a length of the recessed portion 50 that is recessed along the direction away from the center of the groove 310 in the direction parallel to the base substrate.

By defining the recessed depth of the recessed portion 50 to be within the above range, the recessed depth of the recessed portion 50 is prevented from being too large, otherwise, the amount of light directly incident from the light-emitting unit 21 to the first sub-layer 31 is reduced and the light exiting toward the periphery of the display panel is reduced. In this way, the light uniformly exits from the display panel are various locations.

In some embodiments, the recessed depth H of the recessed portion 50 ranges from 1 μm to 3 μm. In some embodiments, the recessed depth of the recessed portion 50 is 2 μm.

In some embodiments, the orthographic projection of the recessed portion on the bearing surface is in the shape of a regular polygon, a circle, an ellipse, or any irregular closed shape.

In some embodiments, as illustrated in FIG. 27, the orthographic projection of the recessed portion 50 on the bearing surface is in the shape of a rectangle. A length of the rectangle ranges from 1 μm to 2 μm, and a width of the rectangle, i.e., the recessed depth H of the recessed portion 50, ranges from 1 μm to 3 μm.

In some embodiments, as illustrated in FIG. 28, the orthographic projection of the recessed portion 50 on the bearing surface is in the shape of a trapezoid. A length of the rectangle ranges from 1 μm to 2 μm, and a height of the rectangle, i.e., the recessed depth H of the recessed portion 50, ranges from 1 μm to 3 μm.

In the above embodiments, the side wall of the groove 310 is an inclined surface, and accordingly, the side wall on which an upper base of the trapezoid is disposed is also an inclined surface, and an inclination angle between the side wall of the groove 310 and the driver backplane 10 is equal to an inclination angle between the side wall on which the upper base of the trapezoid is disposed and the driver backplane 10.

By defining the side wall of the groove 310 to be parallel to the side wall where the upper base of the trapezoid is disposed, the light obliquely incident to the side wall of the first sub-layer 31 and the light incident to the side wall where the upper base of the trapezoid is disposed, of which the incident angles are the same, are capable of exiting from the light-exiting surface of the display panel at the same exiting angle.

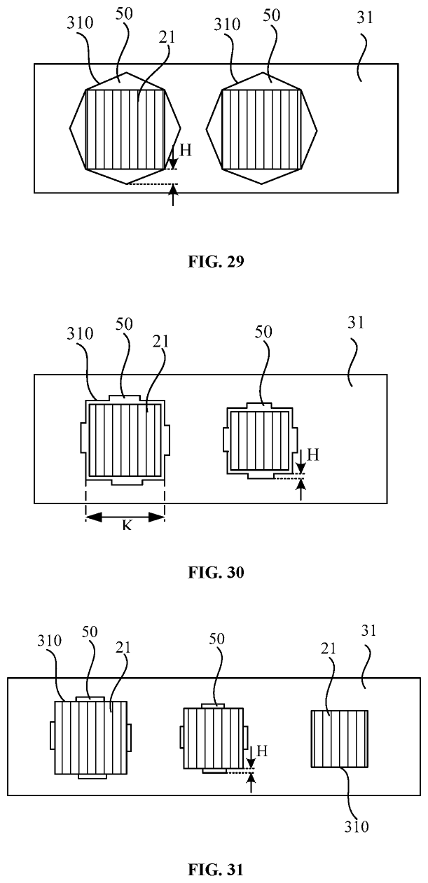

In some embodiments, as illustrated in FIG. 29, the orthographic projection of the recessed portion 50 on the bearing surface is in the shape of a triangle. The triangle is an isosceles triangle. In the direction parallel to the driver backplane 10, a length of the bottom base of the isosceles triangle is equal to a length of the side wall of the groove 310, and a distance between a vertex of the isosceles triangle and the bottom base, i.e., the recessed depth H of the recessed portion 50, ranges from 1 μm to 3 μm.

In the case that the orthographic projection of the recessed portion 50 is in the shape of a triangle, compared to the orthographic projection of the recessed portion 50 being rectangular or trapezoidal, an area of the orthographic projection of the recessed portion 50 on the bearing surface is larger, such that more light is allowed to be reflected at the surface of the recessed portion 50.

In the above embodiments, the orthographic projection of the groove, except for the outer profile of the recessed portion, on the bearing surface coincides with the orthographic projection of the light-emitting unit 21 on the bearing surface. That is, the orthographic projection of the groove, except for the outer profile of the recessed portion, on the bearing surface is the same as an extent defined by the opening of the pixel-definition layer 23.

In other embodiments, as illustrated in FIG. 30, the outer profile of the orthographic projection of the groove 310 on the bearing surface is outside the orthographic projection of the light-emitting unit 21 on the bearing surface. The width K of the groove 310 is greater than the length of the opening of the pixel-definition layer.

In other embodiments, as illustrated in FIG. 31, some of the grooves 310 are provided with the recessed portions 50 in their side walls, and some of the grooves 310 are not provided with the recessed portions 50. On the premise of defining sufficient recessed portions to allow more light to be reflected at the surfaces of the recessed portions 50 and to enhance the forward light-exiting efficiency of the light-emitting unit 21, it is possible to not define the recessed portions in some of the grooves to prevent the problem of light mixing from occurring between the light-emitting units.

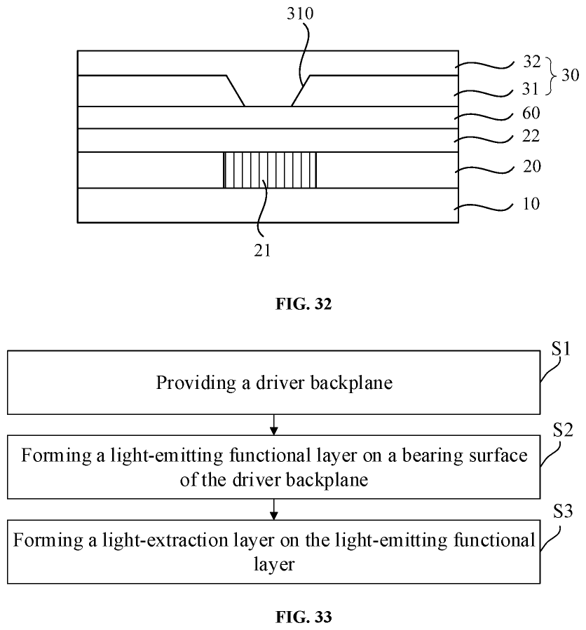

FIG. 32 is a sectional schematic diagram of a display panel according to some embodiments of the present disclosure. As illustrated in FIG. 32, the display panel further includes a touch control layer 60 and a package layer 22. The package layer 22 and the touch control layer 60 are successively stacked between the light-emitting functional layer 20 and the light-extraction layer 30, and the first sub-layer 31 and the second sub-layer 32 are successively stacked on the touch control layer 60.

In some embodiments, the touch control layer 60 includes a plurality of touch control units and a plurality of touch control lines. The plurality of touch control units are arranged in arrays on the package layer 22, and the plurality of touch control lines are disposed on the package layer 22. The touch control lines are connected to at least one of the touch control units, and the touch control lines are configured to electrically connect the connected touch control units to a touch control integrated circuit.

In some embodiments, the touch control unit is a transparent conductive layer, such as an indium tin oxide (ITO) layer and an indium zinc oxide (IZO) layer.

In some embodiments, the touch control unit is a metal mesh structure. The metal mesh structure is formed by metal wires interweaved with each other and in the form of a network. The touch control unit of this structure is a touch control unit of a touch control layer in the flexible multi-layer on cell (FMLOC) technology.

The metal mesh structure is formed by metal wires. To avoid the metal mesh structure blocking the light emitted from the light-emitting unit 21, the metal mesh structure is distributed around the light-emitting unit 21, such that the display effect of the display substrate is ensured.

FIG. 33 is a flowchart of a method for manufacturing a display panel according to some embodiments of the present disclosure. As illustrated in FIG. 33, the method includes the following steps

In step S1, a driver backplane is provided.

The driver backplane includes a base substrate and a plurality of driver circuits, wherein the plurality of driver circuits are arranged in arrays on the base substrate.

In some embodiments, the driver backplane is a TFT substrate, and each of the driver circuits on the driver backplane includes at least 2 TFTs.

In step S2, a light-emitting functional layer is formed on a bearing surface of the driver backplane.

The light-emitting functional layer includes a plurality of light-emitting units arranged in arrays.

In some embodiments, prior to step S3, the method further includes: forming a package layer on the light-emitting functional layer, and then forming a touch control layer on the package layer.

In step S3, a light-extraction layer is formed on the light-emitting functional layer.

In the case that the touch control layer is formed in the preceding step, the light-extraction layer formed in step S3 is on the touch control layer.

As illustrated in FIG. 2, the light-extraction layer 30 includes a first sub-layer 31 and a second sub-layer 32. The first sub-layer 31 and the second sub-layer 32 are successively stacked on the light-emitting functional layer 20. A refractive index of the first sub-layer 31 is less than a refractive index of the second sub-layer 32. A plurality of grooves 310 are defined in the first sub-layer 31. Each of the grooves 310 is opposite to one light-emitting unit 21, and a portion of the second sub-layer 32 is within the groove 310.

At least a portion of an outer profile of an orthographic projection of the groove 310 on the bearing surface is within an orthographic projection of the corresponding light-emitting unit 21 on the bearing surface.

In some embodiments, a protrusion is formed on a side wall of the groove, and an orthographic projection of the protrusion on the base substrate of the driver backplane is within the orthographic projection of the light-emitting unit on the base substrate of the driver backplane.

The number and the shape of protrusions, and the positional relation between the protrusion and the groove refer to the embodiments illustrated in the preceding FIG. 1 to FIG. 11.

Some embodiments of the present disclosure provide a display device. The display device includes a display panel as described above and a power supply component. The power supply component is electrically connected to the display panel. The power supply component is a power supply.

The display device is a smartphone, a tablet computer, a television, a monitor, a laptop computer, a digital photo frame, a navigator, and any other product or component having a display function.

The technical solutions according to the embodiments of the present disclosure achieve at least the following beneficial effects.

In the display panel according to some embodiments of the present disclosure, the driver backplane, the light-emitting functional layer, and the light-extraction layer are successively stacked, wherein two stacked sub-layers with different refractive indices are arranged on the light-emitting functional layer. The grooves are defined in first sub-layer with a low refractive index, and the second sub-layer with a high refractive index is partially within the grooves to fill the grooves. In this way, in the case that light is obliquely incident from the light-emitting functional layer to the interface between the side wall of the groove and the second sub-layer, reflection occurs because the light is incident from the second sub-layer having a high refractive index to the first sub-layer having a low refractive index. Therefore, the exiting direction of the light obliquely exiting, is changed, such that the light is capable of exiting from the light-exiting surface of the display panel after being reflected at the interface, and thus the forward light-exiting efficiency is improved.

The described above are not intended to limit the present disclosure in any form, although the present disclosure has been disclosed as above by embodiments, and those skilled in the art, without departing from the scope of the technical solutions of the present disclosure, may utilize the technical contents disclosed above to make some changes or modifications to obtain equivalent embodiments. Any modifications, equivalent substitutions, improvements, and the like made within the spirit and principles of the present disclosure shall be included in the protection scope of the present disclosure.

1. A display panel, comprising: a driver backplane, a light-emitting functional layer, and a light-extraction layer, the light-emitting functional layer and the light-extraction layer being successively disposed on a bearing surface of the driver backplane; wherein
the light-emitting functional layer comprises a plurality of light-emitting units arranged in arrays; and
the light-extraction layer comprises a first sub-layer and a second sub-layer, wherein the first sub-layer and the second sub-layer are successively stacked on the light-emitting functional layer, a refractive index of the first sub-layer is less than a refractive index of the second sub-layer, a plurality of grooves are defined in the first sub-layer, each of the plurality of grooves is opposite to one of the plurality of light-emitting units, a portion of the second sub-layer is within the plurality of grooves, and a boundary length of the groove is greater than a boundary length of a light-emitting region of the corresponding one of the light-emitting units.

2. The display panel according to claim 1, wherein at least a portion of an outer profile of an orthographic projection of the groove on the bearing surface is within an orthographic projection of the corresponding light-emitting unit on the bearing surface.

3. The display panel according to claim 2, wherein a protrusion is formed on a side wall of at least one of the plurality of grooves, wherein the protrusion protrudes along a direction toward a center of the groove, and at least a portion of an outer profile of an orthographic projection of the protrusion on the bearing surface is within the orthographic projection of the light-emitting unit on the bearing surface.

4. The display panel according to claim 1, wherein an orthographic projection of the light-emitting unit on the bearing surface is within an outer profile of an orthographic projection of the groove on the bearing surface.

5. The display panel according to claim 4, wherein a protrusion is formed on a side wall of at least one of the plurality of grooves, the protrusion protruding along a direction toward a center of the groove.

6. The display panel according to claim 3, wherein a maximum length of the protrusion ranges from 1 μm to 3 μm, and a maximum width of the protrusion ranges from 1 μm to 5 μm.

7. The display panel according to claim 3, wherein a shape of a section, parallel to the bearing surface, of the protrusion comprises an arc.

8. The display panel according to claim 3, wherein an outer wall surface of the protrusion is a conical surface, and a large-sized end of the protrusion is proximal to the light-emitting unit.

9. (canceled)

10. The display panel according to claim 3, wherein a plurality of the protrusions are provided, and the plurality of the protrusions are spaced apart around a geometric center of the groove.

11. The display panel according to claim 10, wherein the groove has a plurality of side walls successively connected end to end, at most one of the protrusions is formed on each of the side walls of the groove.

12. The display panel according to claim 11, wherein the plurality of light-emitting units comprise a first light-emitting unit, the groove corresponding to the first light-emitting unit comprises a first side wall, a third side wall, a second side wall, and a fourth side wall that are successively connected, and one of the protrusions is formed on each of the side walls of the groove; wherein
a line connecting a geometrical center of the protrusion of the first side wall to a geometrical center of the protrusion of the second side wall is a first connection line, the first connection line being intersected with an extension line of a side edge, proximal to the first light-emitting unit, of the third side wall or an extension line of a side edge, proximal to the first light-emitting unit, of the fourth side wall; or
a line connecting a geometrical center of the protrusion of the third side wall to a geometrical center of the protrusion of the fourth side wall is a second connection line, the second connection line being intersected with an extension line of a side edge, proximal to the first light-emitting unit, of the first side wall or an extension line of a side edge, proximal to the first light-emitting unit, of the second side wall.

13. The display panel according to claim 12, wherein each of the first side wall, the second side wall, the third side wall, and the fourth side wall comprises a straight line segment; wherein
at least one side edge of the first side wall, the second side wall, the third side wall, and the fourth side wall further comprises a curved line segment, the curved line segment being connected to an end of the straight line segment of the side edge on which the curved line segment is disposed; and
the protrusions on the first side wall, the second side wall, the third side wall, and the fourth side wall are respectively disposed at midpoints of the corresponding straight line segments.

14. The display panel according to claim 12, wherein the plurality of light-emitting units are arranged in a matrix in a first direction and a second direction, wherein the first connection line is intersected with both the first direction and the second direction, and/or the second connection line is intersected with both the first direction and the second direction.

15. The display panel according to claim 14, wherein the plurality of light-emitting units further comprise a second light-emitting unit and a third light-emitting unit, each of the second light-emitting unit and the third light-emitting unit comprising four successively connected side walls and protrusions respectively disposed on the side walls; wherein
the opposite two protrusions on the second light-emitting unit are arranged along a first straight line or a second straight line, and the opposite two protrusions on the third light-emitting unit are arranged along the first straight line or the second straight line, the first straight line being parallel to the first direction and the second straight line being parallel to the second direction.

16. The display panel according to claim 15, wherein each of the first side wall and the fourth side wall of the first light-emitting unit comprises a straight line segment and a curved line segment, wherein the curved line segment of the first side wall is connected to the curved line segment of the fourth side wall, and the connected two curved line segments form a fillet; and
the protrusion on the first side wall of the first light-emitting unit is not overlapped with the second straight line, the protrusion on the fourth side wall of the first light-emitting unit is not overlapped with the first straight line, the protrusion on the second side wall of the first light-emitting unit is on the second straight line, and the protrusion on the third side wall of the first light-emitting unit is on the first straight line; or
the protrusion on the first side wall of the first light-emitting unit is on the second straight line, the protrusion on the fourth side wall of the first light-emitting unit is on the first straight line, the protrusion on the second side wall of the first light-emitting unit is not overlapped with the second straight line, and the protrusion on the third side wall of the first light-emitting unit is not overlapped with the first straight line.

17. (canceled)

18. The display panel according to claim 1, wherein a recessed portion is defined in a side wall of the groove; wherein
the recessed portion is recessed along a direction away from a geometrical center of the groove, and the recessed portion is disposed at least in a side surface, proximal to the light-emitting functional layer, of the first sub-layer; and
at least a portion of an orthographic projection of the recessed portion on the bearing surface is outside an orthographic projection of the corresponding light-emitting unit on the bearing surface.

19. (canceled)

20. (canceled)

21. The display panel according to claim 1, wherein the groove has a first opening and a second opening, wherein the first opening is disposed in a side surface, proximal to the driver backplane, of the first sub-layer, and the second opening is disposed in a side surface, distal from the driver backplane, of the first sub-layer, and an orthographic projection of the first opening on the bearing surface is within an orthographic projection of the second opening on the bearing surface.

22. (canceled)

23. (canceled)

24. (canceled)

25. (canceled)

26. (canceled)

27. The display panel according to claim 1, further comprising: a touch control layer and a package layer, wherein the package layer and the touch control layer are successively stacked between the light-emitting functional layer and the light-extraction layer, and the first sub-layer and the second sub-layer are successively stacked on the touch control layer.

28. A method for manufacturing a display panel, comprising:
providing a driver backplane;
forming a light-emitting functional layer on a bearing surface of the driver backplane, wherein the light-emitting functional layer comprises a plurality of light-emitting units arranged in arrays; and
forming a light-extraction layer on the light-emitting functional layer, the light-extraction layer comprising a first sub-layer and a second sub-layer, wherein the first sub-layer and the second sub-layer are successively stacked on the light-emitting functional layer, a refractive index of the first sub-layer is less than a refractive index of the second sub-layer, a plurality of grooves are defined in the first sub-layer, each of the plurality of grooves is opposite to one of the plurality of light-emitting units, a portion of the second sub-layer is within the plurality of grooves, and a boundary length of the groove is greater than a boundary length of a light-emitting region of the corresponding one of the light-emitting units.

29. A display device, comprising: a power supply component and a display panel, wherein
the power supply component is electrically connected to the display panel; and
the display panel comprises: a driver backplane, a light-emitting functional layer, and a light-extraction layer, the light-emitting functional layer and the light-extraction layer being successively disposed on a bearing surface of the driver backplane; wherein
the light-emitting functional layer comprises a plurality of light-emitting units arranged in arrays; and
the light-extraction layer comprises a first sub-layer and a second sub-layer, wherein the first sub-layer and the second sub-layer are successively stacked on the light-emitting functional layer, a refractive index of the first sub-layer is less than a refractive index of the second sub-layer, a plurality of grooves are defined in the first sub-layer, each of the plurality of grooves is opposite to one of the plurality of light-emitting units, a portion of the second sub-layer is within the plurality of grooves, and a boundary length of the groove is greater than a boundary length of a light-emitting region of the corresponding one of the light-emitting units.
